(19) United States
(12) Patent Application Publication
(10) Pub. No.: US 2026/0143910 A1
(43) Pub. Date: May 21, 2026

(54) ORGANIC LIGHT EMITTING ELEMENT

(71) Applicant: TAIZHOU GUANYU TECHNOLOGY CO., LTD., ZHEJIANG PROVINCE (CN)

(72) Inventors: HUEI-SIOU CHEN, TAIPEI CITY (TW); KUO-CHENG HSU, TAICHUNG CITY (TW); YICHANG WANG, ZHEJIANG PROVINCE (CN)

(21) Appl. No.: 19/370,785

(22) Filed: Oct. 28, 2025

Related U.S. Application Data
(60) Provisional application No. 63/722,081, filed on Nov. 19, 2024.

(30) Foreign Application Priority Data
Nov. 15, 2024 (CN) 202411640509.2
Aug. 29, 2025 (CN) 202511231884.6

(51) Int. Cl. H10K 50/858; H10K 50/852; H10K 102/00; H10K 102/10

(52) U.S. Cl. CPC H10K 50/858; H10K 50/852; H10K 2102/101; H10K 2102/351

(57) ABSTRACT

An organic light-emitting element includes multiple organic light-emitting units. Each of the organic light-emitting units includes a substrate, a first electrode located over the substrate, an organic light-emitting layer located over the first electrode, a second electrode located over the organic light-emitting layer, a reflector located on one side of one of the first electrode and the second electrode, and a lens located on an optical path between the organic light-emitting layer and a light exiting surface of the organic light-emitting unit. One of the first electrode and the second electrode includes a transparent conductive material, the reflector enhances intensity of a resonant cavity of the organic light-emitting unit, and the lens enables the organic light-emitting unit to generate a collimated light beam.

### PRIORITY CLAIM AND CROSS-REFERENCE

This application claims the benefit of U.S. Provisional Application No. 63/722,081, filed on November 19, 2024, and claims priority to China Patent Application Serial No. 202411640509.2, filed on November 15, 2024, and China Patent Application Serial No. 202511231884.6, filed on August 29, 2025, the entirety of which are incorporated by reference herein.

### BACKGROUND OF THE DISCLOSURE

### FIELD OF THE DISCLOSURE

The present disclosure relates to an organic light-emitting element, and more particularly to an organic light-emitting element including an organic light-emitting diode (OLED) structure.

### DESCRIPTION OF THE PRIOR ART

Currently, a fine metal mask (FMM) is commonly used in a coating step for forming a light-emitting layer of an organic light-emitting element, or white light in combination with a color film is used for manufacturing an organic light-emitting element. However, fineness or resolution of pixels resulted from the manufacturing process above is rather poor.

### SUMMARY OF THE DISCLOSURE

In the present disclosure, an organic light-emitting element includes a plurality of organic light-emitting units. Each of the organic light-emitting units includes a substrate, a first electrode located over the substrate, an organic light-emitting layer located over the first electrode, a second electrode located over the organic light-emitting layer, a reflector located on one side of one of the first electrode and the second electrode, and a lens located on an optical path between the organic light-emitting layer and a light exiting surface of the organic light-emitting unit. One of the first electrode and the second electrode includes a transparent conductive material, the reflector enhances intensity of a resonant cavity of the organic light-emitting unit, and the lens enables the organic light-emitting unit to generate a collimated light beam.

In some embodiments, the organic light-emitting element includes a first organic light-emitting unit and a second organic light-emitting unit. The first organic light-emitting unit includes: a first organic light-emitting layer, emitting light in a first waveband; and a first lens, enabling the first organic light-emitting unit to generate a collimated light beam. The second organic light-emitting unit includes: a second organic light-emitting layer, emitting light in a second waveband, wherein a wavelength of the light in the second waveband is different from a wavelength of the light in the first waveband; and a second lens, enabling the second organic light-emitting unit to generate a collimated light beam, wherein a size of the second lens is different from a size of the first lens.

In some embodiments, a radius of curvature of the second lens is different from a radius of curvature of the first lens.

In some embodiments, a maximum vertical height of the second lens is different from a maximum vertical height of the first lens.

In some embodiments, the wavelength of the light in the first waveband is less than the wavelength of the light in the second waveband, and the radius of curvature of the first lens is greater than the radius of curvature of the second lens.

In some embodiments, the first organic light-emitting layer has a first thickness, the second organic light-emitting layer has a second thickness, the second thickness is greater than the first thickness, and the maximum vertical height of the second lens is less than the maximum vertical height of the first lens.

In some embodiments, the organic light-emitting units of the organic light-emitting element further include a third organic light-emitting unit. The third organic light-emitting unit includes: a third organic light-emitting layer, emitting light in a third waveband, wherein a wavelength of the light in the third waveband is different from the wavelength of the light in the first waveband; and a third lens, enabling the third organic light-emitting unit to generate a collimated light beam, wherein a size of the third lens is different from the size of the first lens and the size of the second lens.

In some embodiments, the wavelength of the light in the first waveband is less than the wavelength of the light in the second waveband, and the wavelength of the light in the third waveband is less than the wavelength of the light in the first waveband.

In some embodiments, the radius of curvature of the first lens is greater than the radius of curvature of the second lens, and a radius of curvature of the third lens is greater than the radius of curvature of the first lens.

In some embodiments, the first organic light-emitting layer has a first thickness, the second organic light-emitting layer has a second thickness, the third organic light-emitting layer has a third thickness, the first thickness is less than the second thickness, and the third thickness is less than the first thickness.

In some embodiments, the maximum vertical height of the first lens is different from the maximum vertical height of the second lens, and a maximum vertical height of the third lens is greater than the maximum vertical height of the first lens.

In some embodiments, the organic light-emitting element further includes a flat layer, located above the second electrode; and a cover plate, located above the flat layer, wherein the lens is located within the flat layer. In some embodiments, a convex surface of the lens faces the organic light-emitting layer.

In some embodiments, the organic light-emitting element further includes: a first flat layer, located above the second electrode, wherein the lens is located over the first flat layer; a second flat layer, located over the first flat layer and covers the lens; and a cover plate, located over the second flat layer. In some embodiments, the convex surface of the lens faces the cover plate.

In some embodiments, the reflector is located between the first electrode and the substrate.

In some embodiments, the reflector is a first reflector, and the organic light-emitting element further includes a second reflector located between the second electrode and the cover plate, wherein the lens is located between the second reflector and the cover plate.

### BRIEF DESCRIPTION OF THE DRAWINGS

FIG. 1 is a top view of an exemplary intermediate product of an organic light-emitting element;

FIG. 2A is a cross-sectional view of an organic light-emitting element;

FIG. 2B is a cross-sectional view of an organic light-emitting element;

FIG. 2C is a cross-sectional view of an organic light-emitting element;

FIG. 2D is a cross-sectional view of an organic light-emitting element;

FIG. 3A to FIG. 3G depict a manufacturing method of an organic light-emitting element according to some embodiments;

FIG. 4 is a cross-sectional view of an organic light-emitting element;

FIG. 5A is a cross-sectional view of an organic light-emitting element;

FIG. 5B is a cross-sectional view of an organic light-emitting element;

FIG. 5C is a cross-sectional view of an organic light-emitting element;

FIG. 5D is a cross-sectional view of an organic light-emitting element; and

FIG. 6A to FIG. 6H depict a manufacturing method of an organic light-emitting element according to some embodiments.

### DETAILED DESCRIPTION OF THE EMBODIMENTS

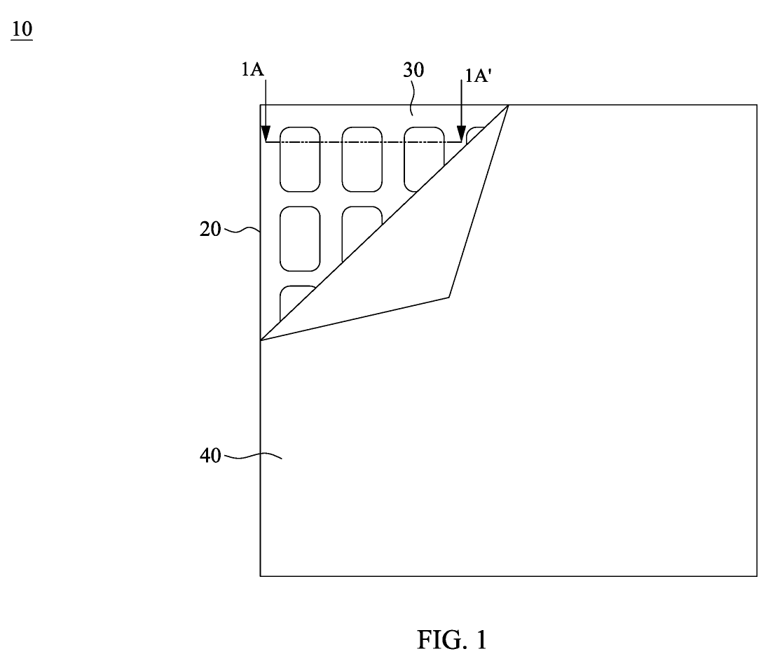

FIG. 1 shows a top view of an exemplary intermediate product of an organic light-emitting element 10. The light-emitting element 10 includes a light-emitting layer 20 and a cover layer 40 located over the light-emitting layer 20. For the light-emitting layer 20, a spacer structure 30 may be designed to define a pixel region so as to define a light-emitting pixel array.

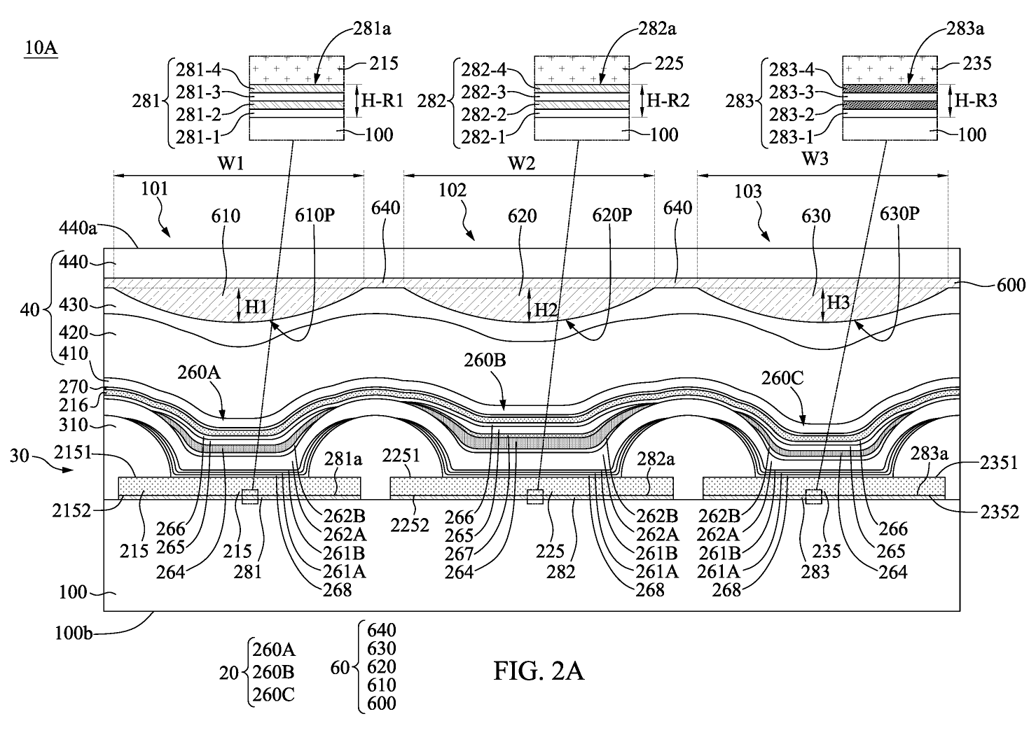

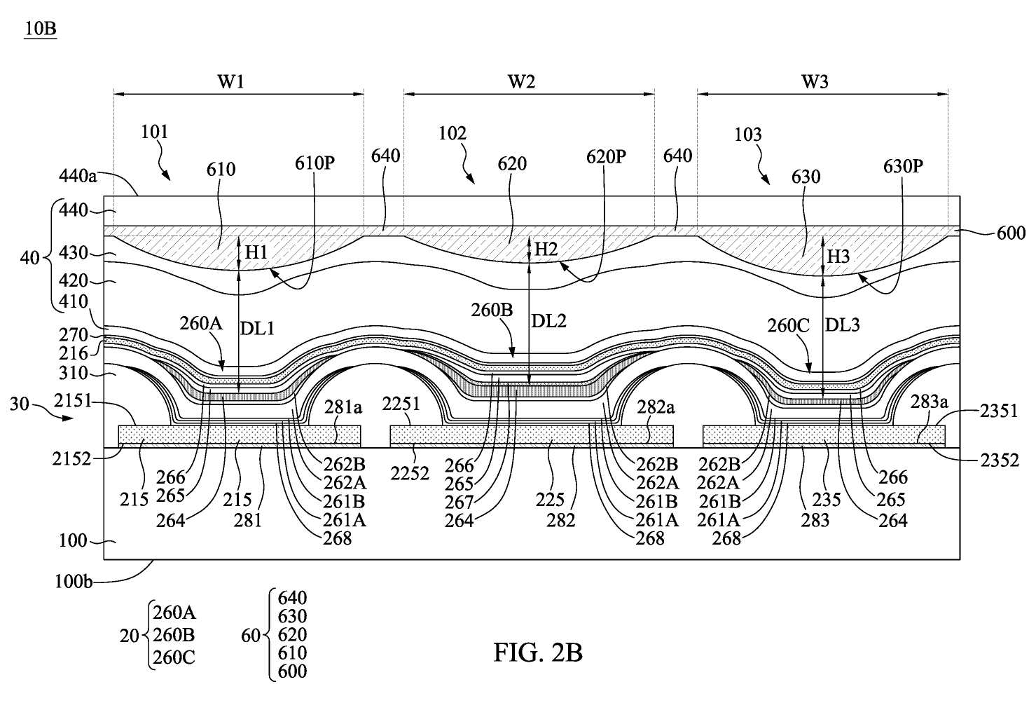

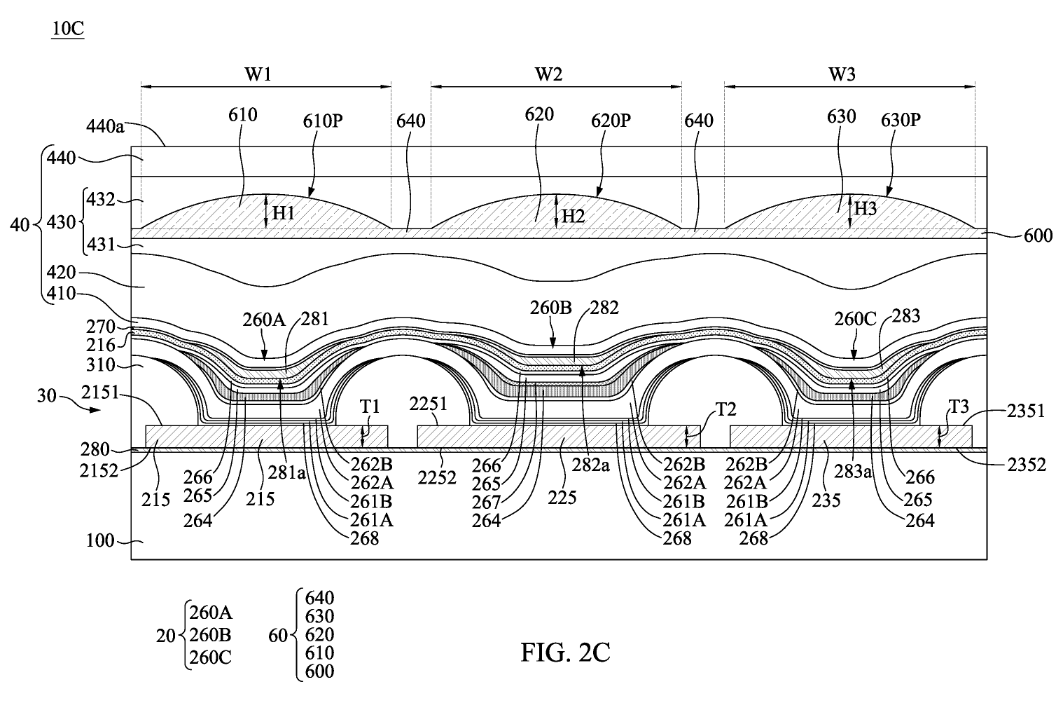

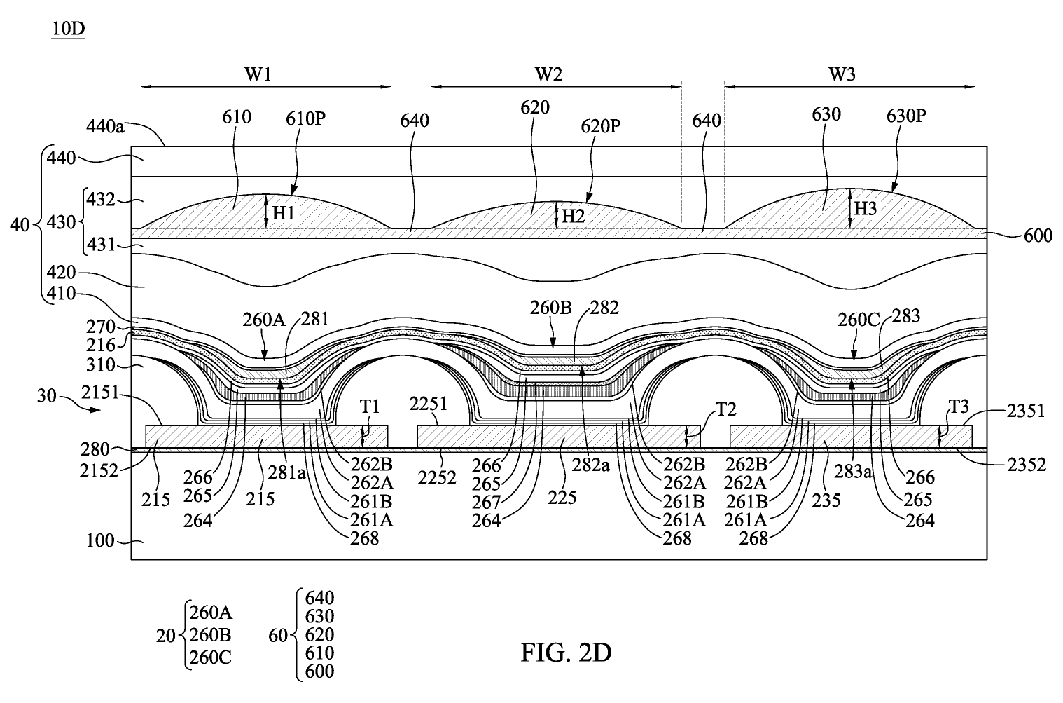

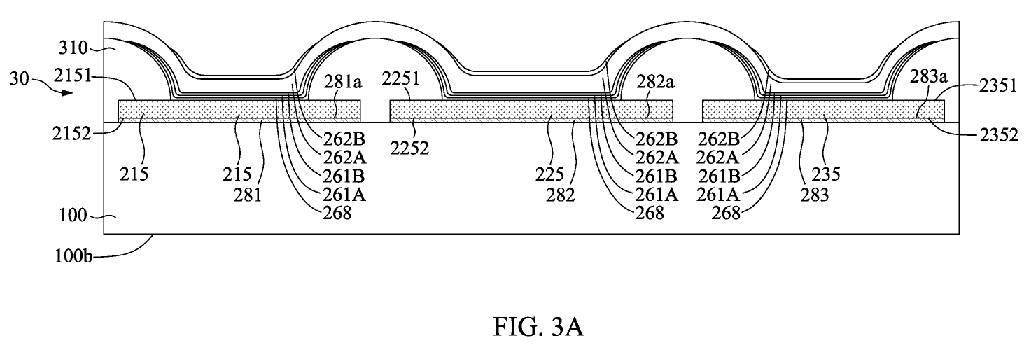

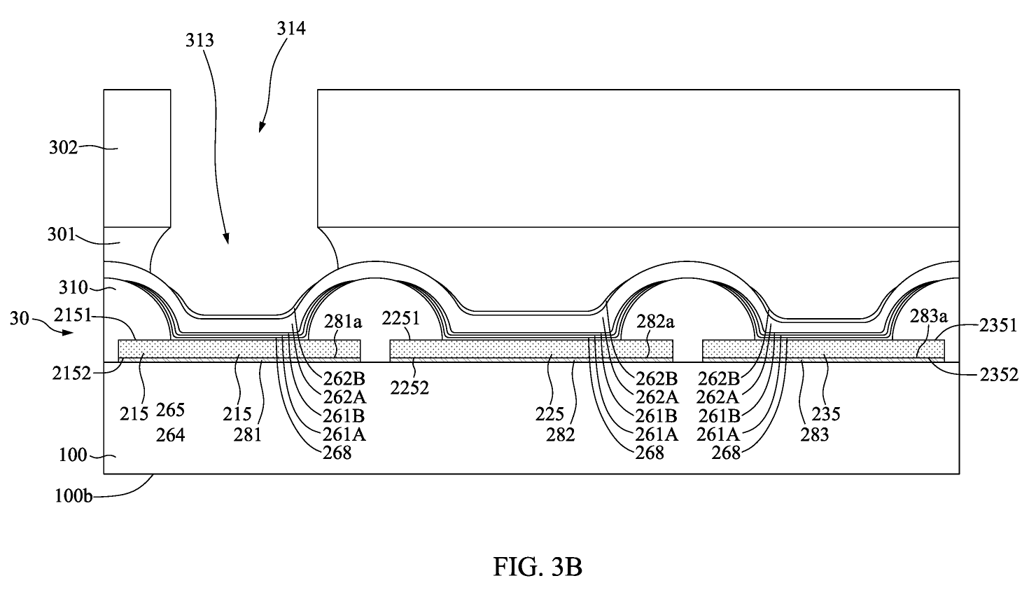

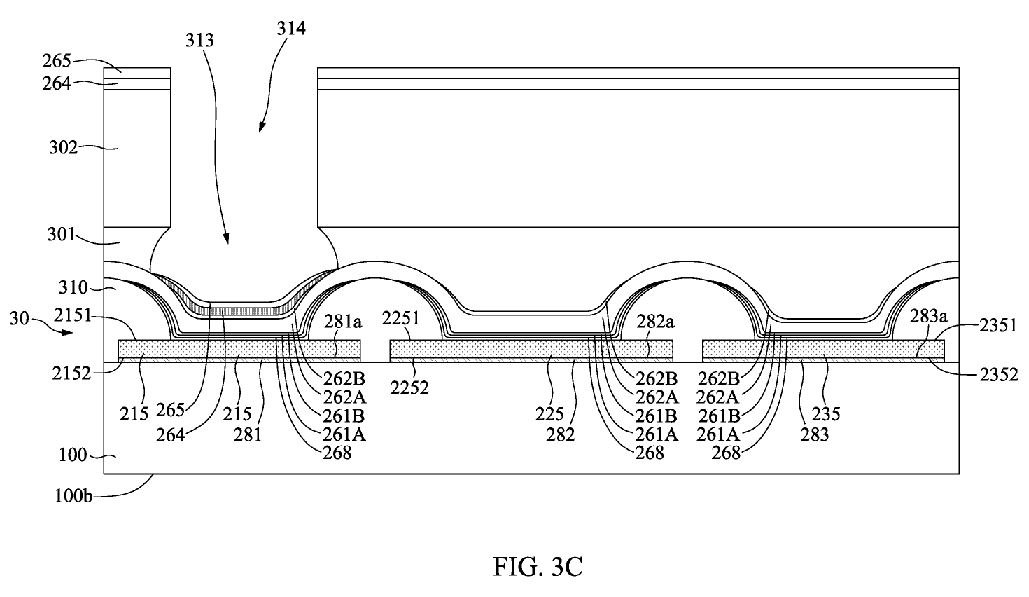

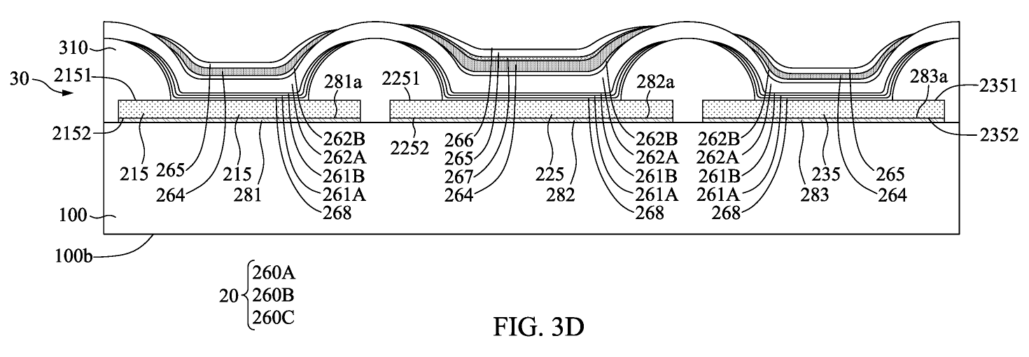

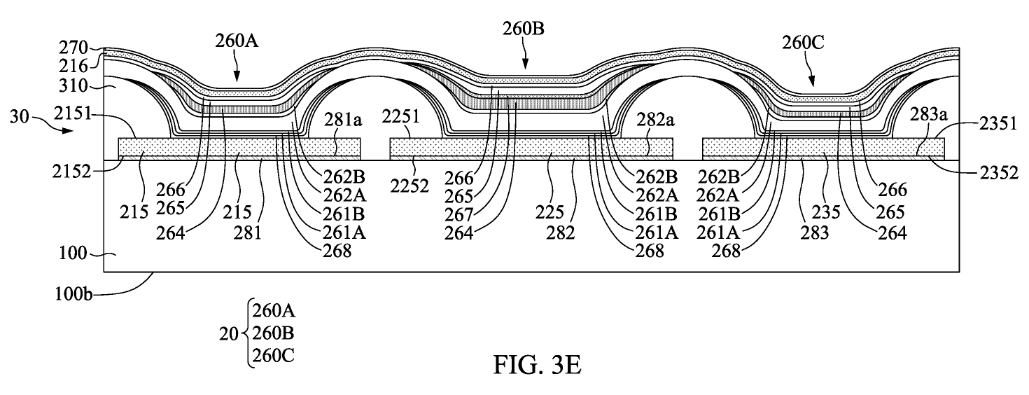

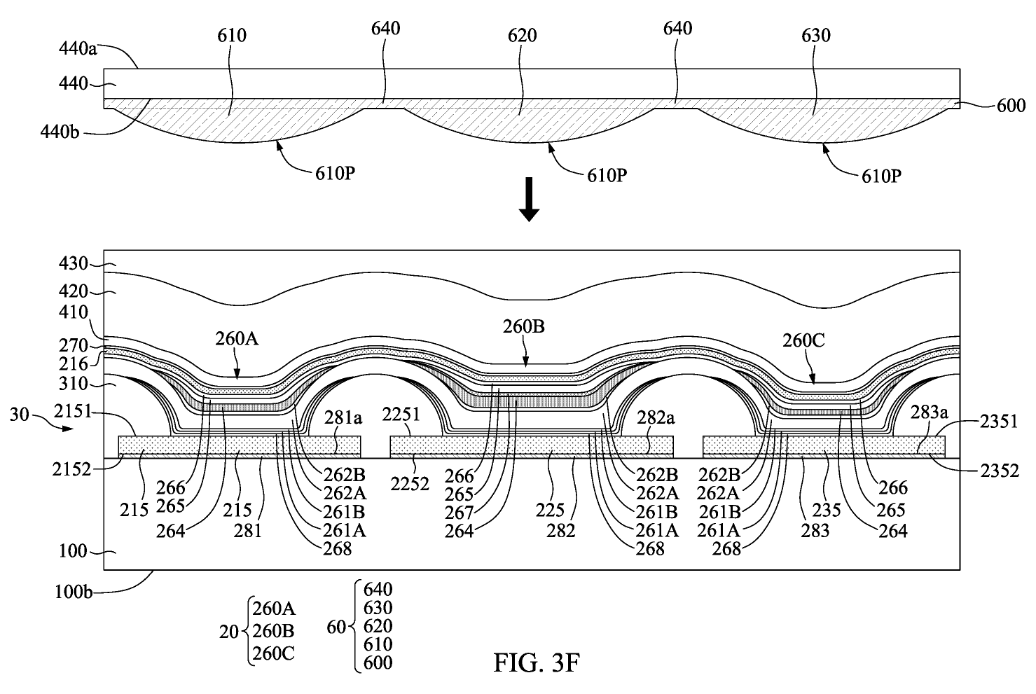

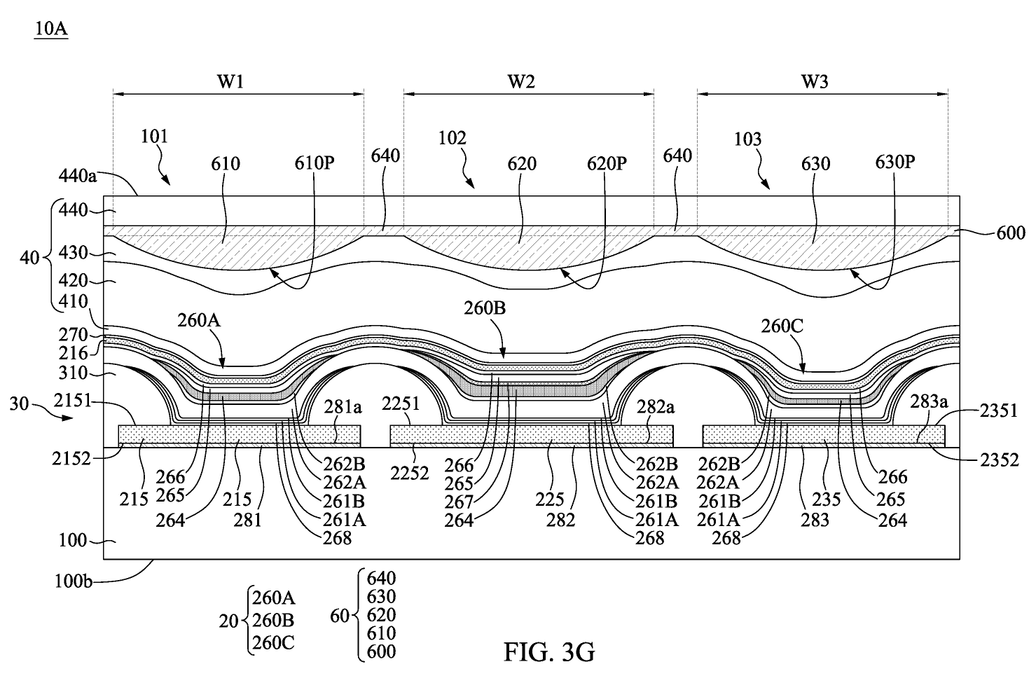

In some embodiments, the spacer structure 30 includes pixel defined layers (PDL) 310, for example, protrusions, to provide a recess array used to accommodate the light-emitting pixel array. In some embodiments, the spacer structure 30 may include a photosensitive material made into protrusions. The protrusions may serve as the pixel defined layers 310. Thus, in some embodiments shown in FIG. 2A to FIG. 2D and FIG. 3A to FIG. 3G, the protrusions may be referred to as protrusions 310.

FIG. 2A is a cross-sectional view of an organic light-emitting element 10A. In some embodiments, FIG. 2A is a cross-sectional view taken along the line 1A-1A’ in FIG. 1. In some embodiments, FIG. 2A is a cross-sectional view taken along the line 1A-1A’ in FIG. 1, and only a light-emitting region is illustrated. The spacer structure 30 includes a plurality of protrusions 310 to define a light-emitting pixel pattern. A recess is located between two adjacent protrusions 310 and provides a space for accommodating light-emitting pixels. When viewing the cross-sectional diagram shown in FIG. 2A, a person skilled in the art would be able to understand that the protrusions 310 are depicted in a disconnected manner. However, when viewing the schematic top view of FIG. 1, the protrusions 310 can be connected to one another by other parts of the spacer structure 30.

As shown in FIG. 2A, in some embodiments, the organic light-emitting element 10A is, for example, a light-emitting element including an organic light-emitting diode (OLED) structure. In some embodiments, the light-emitting element 10 includes a plurality of organic light-emitting units (or referred to as light-emitting pixels), for example, including at least an organic light-emitting unit 101 (or referred to as a first organic light-emitting unit), an organic light-emitting unit 102 (or referred to as a second organic light-emitting unit), and an organic light-emitting unit 103 (or referred to as a third organic light-emitting unit). In some embodiments, the organic light-emitting units 101, 102 and 103 are between the protrusions 310 and above the substrate 100. The organic light-emitting units 101, 102 and 103 may emit light having the same wavelength or light having different wavelengths.

In some embodiments, the organic light-emitting element 10 includes a substrate 100, an electrode 215, an electrode 225, an electrode 235, an electrode 216, a light-emitting layer 20, an inorganic barrier layer 268, an inorganic barrier layer 270, a reflector 281, a reflector 282, a reflector 283, a spacer structure 30, a cover layer 40 and a lens structure 60.

In some embodiments, the substrate 100 may include a transistor array, which is configured to correspond to light-emitting pixels in the light-emitting layer 20. The substrate 100 may include a plurality of capacitors. In some embodiments, more than one transistor is configured with one capacitor and one light-emitting pixel to form a circuit. In some embodiments, the substrate 100 may include glass.

In some embodiments, the electrode 215, the electrode 225 and the electrode 235 are located over the substrate 100. In some embodiments, the electrodes 215, 225 and 235 are anodes. The electrodes 215, 225 and 235 may also be referred to as bottom electrodes of the organic light-emitting element 10. In some embodiments, the electrodes 215, 225 and 235 include a metal material, for example, Ag, Al, Mg, Au, AlCu alloy or AgMo alloy. In some embodiments, the electrodes 215, 225 and 235 include indium tin oxide (ITO), indium zinc oxide (IZO) or other appropriate materials.

In some embodiments, the light-emitting layer 20 includes an organic light-emitting layer 260A (or referred to as a first organic light-emitting layer), an organic light-emitting layer 260B (or referred to as a second organic light-emitting layer) and an organic light-emitting layer 260C (or referred to as a third organic light-emitting layer). In some embodiments, the organic light-emitting layer 260A is located over the electrode 215, the organic light-emitting layer 260B is located over the electrode 225, and the organic light-emitting layer 260C is located over the electrode 235. In some embodiments, a thickness of the organic light-emitting layer 260A, a thickness of the organic light-emitting layer 260B and a thickness of the organic light-emitting layer 260C are different from one another. In some embodiments, the thickness of the organic light-emitting layer 260B is greater than the thickness of the organic light-emitting layer 260A, and the thickness of the organic light-emitting layer 260A is greater than the thickness of the organic light-emitting layer 260C.

In some embodiments, the organic light-emitting layers 260A, 260B and 260C emit light having the same color or different colors. In some embodiments, the organic light-emitting layers 260A, 260B and 260C respectively emit light in a first waveband, a second waveband and a third waveband, and wavelengths of the light (or referred to as luminescence wavelengths of the organic light-emitting layers) in the first waveband, the second waveband and the third waveband are different. In some embodiments, the luminescence wavelength of the organic light-emitting layer 260B is greater than the luminescence wavelength of the organic light-emitting layer 260A, and the luminescence wavelength of the organic light-emitting layer 260A is greater than the luminescence wavelength of the organic light-emitting layer 260C. In some embodiments, the organic light-emitting layer 260A emits green light (for example, light having a wavelength of about 500 nm to about 580 nm), the organic light-emitting layer 260B emits red light (for example, light having a wavelength of about 620 nm to about 780 nm), and the organic light-emitting layer 260C emits blue light (for example, light having a wavelength of about 400 nm to about 500 nm).

In some embodiments, the organic material layers of the organic light-emitting layers 260A, 260B and 260C include an organic material, which may be placed in any of the organic material layers of the organic light-emitting layers 260A, 260B and 260C according to different embodiments. In some embodiments, for a specific wavelength, the organic material has an absorption rate of greater than or equal to 50%, greater than or equal to 60%, greater than or equal to 70%, greater than or equal to 80%, or greater than or equal to 90%. In some embodiments, the organic material has an absorption rate of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

As shown in FIG. 2A, in some embodiments, the organic light-emitting unit 101 includes the electrode 215, the organic light-emitting layer 260A, and the electrode 216. In some embodiments, the electrode 216 is a cathode. The electrode 216 may also be referred to as a top electrode of the organic light-emitting element. In some embodiments, the organic light-emitting layer 260A includes multiple organic material layers, for example, a hole injection layer (HIL) 261A, a hole injection layer (HIL) 261B, a hole transport layer (HTL) 262A, a hole transport layer (HTL) 262B, an organic emissive layer (EML) 264, an electron transport layer (ETL) 265 and an electron injection layer (EIL) 266. In some embodiments, the electrode 216 is located above the organic light-emitting layer 260A.

As shown in FIG. 2A, in some embodiments, the organic light-emitting unit 102 includes the electrode 225, the organic light-emitting layer 260B, and the electrode 216. In some embodiments, the organic light-emitting layer 260B includes multiple organic material layers, for example, the hole injection layer (HIL) 261A, the hole injection layer (HIL) 261B, the hole transport layer (HTL) 262A, the hole transport layer (HTL) 262B, the organic emissive layer (EML) 264, a hole blocking layer (HBL) 267, the electron transport layer (ETL) 265 and the electron injection layer (EIL) 266. In some embodiments, the electrode 216 is located above the organic light-emitting layer 260B.

As shown in FIG. 2A, in some embodiments, the organic light-emitting unit 103 includes the electrode 235, the organic light-emitting layer 260C, and the electrode 216. In some embodiments, the organic light-emitting layer 260C includes multiple organic material layers, for example, the hole injection layer (HIL) 261A, the hole injection layer (HIL) 261B, the hole transport layer (HTL) 262A, the hole transport layer (HTL) 262B, the organic emissive layer (EML) 264, the electron transport layer (ETL) 265 and the electron injection layer (EIL) 266. In some embodiments, the electrode 216 is located above the organic light-emitting layer 260C.

In some embodiments, the organic light-emitting layers 260A, 260B and 260C may have the same thickness or different thicknesses. In some embodiments, the thickness of the organic light-emitting layer 260B is greater than the thickness of the organic light-emitting layer 260A, and the thickness of the organic light-emitting layer 260A is greater than the thickness of the organic light-emitting layer 260C.

In some embodiments, the electrode 216 is in contact with the organic light-emitting layers 260A, 260B and 260C. The electrode 216 may be a continuous film as shown in FIG. 2A and be located above the organic light-emitting layers 260A, 260B and 260C and the protrusions 310. In some embodiments, the electrode 216 may be further located over the spacer structure 30. In some embodiments, the electrode 216 is a common electrode of all light-emitting pixels in the light-emitting layer 20. In some embodiments, the electrode 216 includes a metal material, for example, Ag, Al, Mg, Au, AlCu alloy or AgMo alloy. In some embodiments, the electrode 216 includes, for example, ITO, IZO or other appropriate materials. In other words, the electrode 216 is a common electrode of a plurality of organic light-emitting units. In some embodiments, the electrode 216 is a common electrode of all organic light-emitting units in the organic light-emitting element 10A. In some embodiments, the electrode 216 is a transparent electrode, and for example, includes ITO, IZO or other appropriate materials.

More specifically, in some embodiments, a surface 2151 of the electrode 215 faces the electrode 216, and a surface 2152 opposite to the surface 2151 of the electrode 215 faces the substrate 100 and is in contact with the reflector 281. In some embodiments, the reflector 281 includes a surface 281a, which faces the organic light-emitting layer 260A and is in contact with the electrode 215. Similarly, in some embodiments, a surface 2251 of the electrode 225 faces the electrode 216, and a surface 2252 opposite to the surface 2251 of the electrode 225 faces the substrate 100 and is in contact with the reflector 282. In some embodiments, the reflector 282 includes a surface 282a, which faces the organic light-emitting layer 260B and is in contact with the electrode 225. Similarly, in some embodiments, a surface 2351 of the electrode 235 faces the electrode 216, and a surface 2352 opposite to the surface 2351 of the electrode 235 faces the substrate 100 and is in contact with the reflector 283. In some embodiments, the reflector 283 includes a surface 283a, which faces the organic light-emitting layer 260C and is in contact with the electrode 235.

In some embodiments, the electrodes 215, 225 and 235 are transparent electrodes, for example, include ITO, IZO or other appropriate materials, and the reflectors are arranged over surfaces of the electrodes 215, 225 and 235, so as to enhance reflectances on sides of the electrodes 215, 225 and 235 for light emitted by the organic light-emitting layers 260A, 260B and 260C, achieving an effect of a resonant cavity. In some embodiments, the reflectors 281, 282 and 283 are respectively located between the substrate 100 and the electrodes 215, 225 and 235, for example, located over a top surface opposite to a bottom surface 100b of the substrate 100. In some embodiments, the light exiting surface of the organic light-emitting element 10A is the surface 440a of a cover plate 440.

In some embodiments, each of the reflectors 281, 282 and 283 includes silver, a distributed Bragg reflector (DBR) or other appropriate reflective materials. In an embodiment where the reflector is a DBR, the DBR is formed by stacking in alternate multiple layers of dielectric materials with different refractive indices, and reflection is generated within the DBR by way of differences of the refractive indices of the different dielectric materials. In some embodiments, a reflector may generate reflection on a contact surface with a transparent electrode.

Regardless of generating reflection within a reflector (for example, a DBR) in some embodiments, generating reflection on a surface of a reflector in some other embodiments, generating reflection on a contact surface of a reflector with a transparent electrode in some other embodiments, or generating reflection inside a transparent electrode in some other embodiments, the reflector and the transparent electrode in contact with each other may be regarded as a reflective body as a whole to provide reflection for light emitted by an organic light-emitting layer on the side of the electrode. For brevity, expressions such as “reflectance provided by a reflector arranged” or “reflectance provided by a reflector arranged for light emitted by an organic light-emitting layer”, or similar expressions herein, include reflectance provided in any of the possible situations of generating reflection by the reflectors described above.

In some embodiments, for the light emitted by the organic light-emitting layers 260A, 260B and 260C, the reflectance of each of the reflectors 281, 282 and 283 arranged is greater than or equal to 30% (or a light transmittance is less than or equal to 70%), for example, greater than or equal to 30%, greater than or equal to 35%, greater than or equal to 40%, greater than or equal to 45%, greater than or equal to 50%, greater than or equal to 55%, greater than or equal to 60%, greater than or equal to 65%, or greater than or equal to 70%. As the reflectance gets higher, the color purity of light becomes better, and the light diffusion angle of an organic light-emitting element also gets smaller.

In some embodiments, when the reflectances provided by the reflectors 281, 282 and 283 arranged exceed 30%, the full width at half maximum (FWHM) of the luminescence peak spectrum of an organic light-emitting layer may be reduced. In some embodiments, when the reflectances provided by the reflectors 281, 282 and 283 arranged are greater than or equal to 30%, the FWHM of the luminescence peak spectrum of an organic light-emitting layer may be reduced by greater than or equal to 10%. In some embodiments, when the reflectances provided by the reflectors 281, 282 and 283 arranged are greater than or equal to 40%, the FWHM of the luminescence peak spectrum of an organic light-emitting layer may be reduced by greater than or equal to 15%. In some embodiments, when the reflectances provided by the reflectors 281, 282 and 283 arranged are greater than or equal to 50%, the FWHM of the luminescence peak spectrum of an organic light-emitting layer may be reduced by greater than or equal to 20%. In some embodiments, when the reflectances provided by the reflectors 281, 282 and 283 arranged are greater than or equal to 60%, the FWHM of the luminescence peak spectrum of an organic light-emitting layer may be reduced by greater than or equal to 25%.

In some embodiments, when the reflectances provided by the reflectors 281, 282 and 283 arranged are greater than or equal to 30%, the light diffusion angle of an organic light-emitting layer is approximately less than or equal to positive/negative 60°. In some embodiments, when the reflectances provided by the reflectors 281, 282 and 283 arranged are greater than or equal to 40%, the light diffusion angle of an organic light-emitting layer is approximately less than or equal to positive/negative 50°. In some embodiments, when the reflectances provided by the reflectors 281, 282 and 283 arranged are greater than or equal to 50%, the light diffusion angle of an organic light-emitting layer is approximately less than or equal to positive/negative 40°. In some embodiments, when the reflectances provided by the reflectors 281, 282 and 283 arranged are greater than or equal to 60%, the light diffusion angle of an organic light-emitting layer is approximately less than or equal to positive/negative 30°.

In some embodiments, the reflectors 281, 282 and 283 may be connected to one another. In some embodiments, the reflectors 281, 282 and 283 may be arranged and spaced apart. In some embodiments, each of the reflectors 281, 282 and 283 includes a reflective metal or a non-conductive reflective material. In some embodiments, the reflectances get higher as thicknesses of the reflectors 281, 282 and 283 increase. In some embodiments, each of the reflectors 281, 282 and 283 includes silver, a DBR or other appropriate reflective materials.

In some embodiments, a DBR is formed by stacking in alternate multiple layers of dielectric materials with different refractive indices. In some embodiments, the reflectance of a DBR gets higher as the number of layers in the DBR increases.

In some non-limiting embodiments where the reflector 281 is structured as a DBR, the reflector 281 includes multiple dielectric material layers 281-1, 281-2, 281-3 and 281-4 formed between the substrate 100 and the electrode 215 in a bottom-up manner, wherein the refractive index of the dielectric material layer 281-1 is different from the refractive index of the dielectric material layer 281-2, and the refractive index of the dielectric material layer 281-3 is different from the refractive index of the dielectric material layer 281-4. A dielectric material layer with a low refractive index and a dielectric material layer with a high refractive index may form a DBR pair. In some embodiments, a difference between the refractive indices of the dielectric material layer 281-1 and the dielectric material layer 281-2 is greater than or equal to 0.4. In some embodiments, a difference between the refractive indices of the dielectric material layer 281-3 and the dielectric material layer 281-4 is greater than or equal to 0.4. In some embodiments, the refractive indices of the dielectric material layer 281-1 and the dielectric material layer 281-3 are the same or different. In some embodiments, the refractive indices of the dielectric material layer 281-2 and the dielectric material layer 281-4 are the same or different. In some embodiments, the reflector 281 has a total thickness H-R1. Moreover, although two DBR pairs are used as an example of the reflector 281, the present disclosure is not limited to this example. In some embodiments, the reflector 281 may include one DBR pair or multiple DBR pairs so as to enhance the reflectance in the organic light-emitting unit 101 on the anode side.

In some non-limiting embodiments where the reflector 282 is structured as a DBR, the reflector 282 includes multiple dielectric material layers 282-1, 282-2, 282-3 and 282-4 formed between the substrate 100 and the electrode 225 in a bottom-up manner, wherein the refractive index of the dielectric material layer 282-1 is different from the refractive index of the dielectric material layer 282-2, and the refractive index of the dielectric material layer 282-3 is different from the refractive index of the dielectric material layer 282-4. A dielectric material layer with a low refractive index and a dielectric material layer with a high refractive index may form a DBR pair. In some embodiments, a difference between the refractive indices of the dielectric material layer 282-1 and the dielectric material layer 282-2 is greater than or equal to 0.4. In some embodiments, a difference between the refractive indices of the dielectric material layer 282-3 and the dielectric material layer 282-4 is greater than or equal to 0.4. In some embodiments, the refractive indices of the dielectric material layer 282-1 and the dielectric material layer 282-3 are the same or different. In some embodiments, the refractive indices of the dielectric material layer 282-2 and the dielectric material layer 282-4 are the same or different. In some embodiments, the reflector 282 has a total thickness H-R2. Moreover, the reflector 282 is not limited to the example of including two DBR pairs. In some embodiments, the reflector 282 may include one DBR pair or multiple DBR pairs so as to enhance the reflectance in the organic light-emitting unit 102 on the anode side.

Moreover, the reflectance provided by the reflector 282 arranged may be different from or the same as the reflectance provided by the reflector 281 arranged. In some embodiments, a difference between the refractive indices of the dielectric material layers of each DBR pair of the reflector 282 is different from or the same as a difference between the refractive indices of the dielectric material layers of each DBR pair of the reflector 281. In some embodiments, the number of DBR pairs of the reflector 282 is different from or the same as the number of DBR pairs of the reflector 281. In some embodiments, the total thickness H-R2 of the reflector 282 is different from or the same as the total thickness H-R1 of the reflector 281.

In some non-limiting embodiments where the reflector 283 is structured as a DBR, the reflector 283 includes multiple dielectric material layers 283-1, 283-2, 283-3 and 283-4 formed between the substrate 100 and the electrode 235 in a bottom-up manner, wherein the refractive index of the dielectric material layer 283-1 is different from the refractive index of the dielectric material layer 283-2, and the refractive index of the dielectric material layer 283-3 is different from the refractive index of the dielectric material layer 283-4. A dielectric material layer with a low refractive index and a dielectric material layer with a high refractive index may form a DBR pair. In some embodiments, a difference between the refractive indices of the dielectric material layer 283-1 and the dielectric material layer 283-2 is greater than or equal to 0.4. In some embodiments, a difference between the refractive indices of the dielectric material layer 283-3 and the dielectric material layer 283-4 is greater than or equal to 0.4. In some embodiments, the refractive indices of the dielectric material layer 283-1 and the dielectric material layer 283-3 are the same or different. In some embodiments, the refractive indices of the dielectric material layer 283-2 and the dielectric material layer 283-4 are the same or different. In some embodiments, the reflector 283 has a total thickness H-R3. Moreover, the reflector 283 is not limited to the example of including two DBR pairs. In some embodiments, the reflector 283 may include one DBR pair or multiple DBR pairs so as to enhance the reflectance in the organic light-emitting unit 103 on the anode side.

Moreover, in some embodiments, the reflectance provided by the reflector 283 arranged may be different from or the same as the reflectance provided by the reflector 282 arranged. In some embodiments, the reflectance provided by the reflector 283 arranged may be different from or the same as the reflectance provided by the reflector 281 arranged. In some embodiments, a difference between the refractive indices of the dielectric material layers of each DBR pair of the reflector 283 is different from or the same as the difference between the refractive indices of the dielectric material layers of each DBR pair of the reflector 282. In some embodiments, the difference between the refractive indices of the dielectric material layers of each DBR pair of the reflector 283 is different from or the same as the difference between the refractive indices of the dielectric material layers of each DBR pair of the reflector 281. In some embodiments, the number of DBR pairs of the reflector 283 is different from or the same as the number of DBR pairs of the reflector 282, and is different from or the same as the number of DBR pairs of the reflector 281.

Moreover, in some embodiments, the reflectance gets higher as a thickness of a reflector increases. In some embodiments, the total thickness H-R3 of the reflector 283 is different from or the same as the total thickness H-R1 of the reflector 281. In some embodiments, the total thickness H-R3 of the reflector 283 is different from or the same as the total thickness H-R2 of the reflector 282. In some embodiments where a reflector is structured as a DBR, the reflectance of the reflector is determined by differences between refractive indices of individual dielectric material layers forming the DBR and a number of cycles of the DBR. As the number of pairs of DBR (or referred to as the number of cycles of a DBR) of a reflector increases, the thickness of the reflector gets larger and the reflectance also becomes higher.

In some embodiments, the spacer structure 30 is located over the substrate 100 and partially covers the electrodes 215, 225 and 235. In some embodiments, the spacer structure 30 is located among the organic light-emitting layers 260A, 260B and 260C. In some embodiments, the spacer structure 30 may include the protrusions 310. In some embodiments, the pattern of the spacer structure 30 is designed according to a pixel layout. In some embodiments, the spacer structure 30 serves as a pixel defined layer (PDL). In some embodiments, the protrusions 310 define a pixel region. In some embodiments, each protrusion 310 fills a gap between two adjacent ones of the electrodes 215, 225 and 235. Each of the electrodes 215, 225 and 235 is partially covered by the protrusion 310. In some embodiments, the spacer structure 30 includes an organic insulating material. In some embodiments, the spacer structure 30 includes a photosensitive material. In some embodiments, the spacer structure 30 may further include quantum dots, which have excellent light absorption performance. In some embodiments, the spacer structure 30 may further include a carbon black material, for example, carbon black nanoparticles, conductive fibers containing carbon black, or the like. In some embodiments, the spacer structure 30 may further include a blackbody material, which has an absorption rate of greater than or equal to 90%, 95%, 99%, 99.5%, or 99.9% for visible light.

In some embodiments, for a specific wavelength, the spacer structure 30 has an absorption rate of greater than or equal to 50%, greater than or equal to 60%, greater than or equal to 70%, greater than or equal to 80%, greater than or equal to 90%, or greater than or equal to 95%. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

Moreover, in some embodiments, the inorganic barrier layer 268 is located between the electrodes 215, 225 and 235 and the organic light-emitting layers 260A, 260B and 260C. In some embodiments, a side surface of the inorganic barrier layer 268 is in contact with the protrusions 310. In some embodiments, the inorganic barrier layer 268 substantially completely covers interfaces between the electrodes 215, 225 and 235 and the organic light-emitting layers 260A, 260B and 260C. In some embodiments, the inorganic barrier layer 268 includes a transition metal oxide. In some embodiments, the inorganic barrier layer 268 includes molybdenum oxide (MoO₃). In some embodiments, a thickness of the inorganic barrier layer 268 is equal to or less than 100 Å. In some embodiments, a ratio of the thickness of the inorganic barrier layer 268 to the thicknesses of the electrodes 215, 225 and 235 is less than 0.1, 0.06 or 0.03. In some embodiments, the inorganic barrier layer 268 and the hole injection layers 261A and 261B may jointly form a hole injection layer of the organic light-emitting layers 260A, 260B and 260C.

According to some embodiments of the present disclosure, the inorganic barrier layer 268 may be used to block metal atoms in the electrode 215 from diffusing into the organic light-emitting layers 260A, 260B and 260C (for example, the hole injection layer 261, the hole transport layer 262, the electron barrier layer 263 and the organic emissive layer 264) to avoid quenching, hence preventing degradation of light-emitting efficiency and further enhancing light-emitting luminance and improving a color rendering index (Ra) of an organic light-emitting element. Moreover, according to some embodiments of the present disclosure, the inorganic barrier layer 268 has an extremely small thickness relative to the electrodes 215, 225 and 235, and so the size in thickness of the organic light-emitting element is not significantly increased and an undesirable increase in a light-emitting path is likewise not resulted.

In some embodiments, the inorganic barrier layer 270 is in contact with a capping layer 410. In some embodiments, the inorganic barrier layer 270 covers the electrode 216. In some embodiments, the capping layer 410 is located over the inorganic barrier layer 270, and is separated from the electrode 216 by the inorganic barrier layer 270. In some embodiments, the inorganic barrier layer 270 substantially completely covers an interface between the electrode 216 and the capping layer 410. In some embodiments, the inorganic barrier layer 270 includes a transition metal oxide. In some embodiments, the inorganic barrier layer 270 includes molybdenum oxide (MoO₃). In some embodiments, a thickness of the inorganic barrier layer 270 is less than or equal to 100 Å. In some embodiments, a ratio of the thickness of the inorganic barrier layer 270 to the thickness of the electrode 216 is less than 0.15, 0.1 or 0.05. In some embodiments, a ratio of the thickness of the inorganic barrier layer 270 to the thickness of the capping layer 410 is less than 0.5, 0.3, or 0.15.

According to some embodiments of the present disclosure, the inorganic barrier layer 270 may be used to block metal atoms in the electrode 216 from diffusing into an organic layer (for example, the capping layer 410), hence preventing degradation of light-emitting efficiency and further enhancing light-emitting luminance and improving a color rendering index (Ra) of an organic light-emitting element. Moreover, according to some embodiments of the present disclosure, the inorganic barrier layer 270 has an extremely small thickness relative to the electrode 216 and the capping layer 410, and so the size in thickness of the organic light-emitting element is not significantly increased and an undesirable increase in a light-emitting path is likewise not resulted.

Moreover, the organic light-emitting element 10A further includes the cover layer 40. In some embodiments, the cover layer 40 includes the capping layer 410, an encapsulation layer 420, a filler layer 430 and the cover plate 440. In some embodiments, the capping layer 410 is arranged over the electrode 216, and is substantially conformal with a non-flat upper surface of the electrode 216. The capping layer 410 may include a dielectric material or an inorganic insulating material, for example, SiO₂. In some embodiments, the capping layer 410 may include a hole transport layer material to extract light lost inside the organic light-emitting element so as to improve light-emitting efficiency. The capping layer 410 may also be referred to as a light extraction layer.

In some embodiments, the encapsulation layer 420 is arranged over the capping layer 410, and is substantially conformal with a non-flat upper surface of the capping layer 410. The encapsulation layer 420 may include an oxide, for example, SiO₂. In some embodiments, the encapsulation layer 420 is substantially conformal with the non-flat upper surface of the capping layer 410, and includes a plurality of recesses corresponding to the organic light-emitting layers 260A, 260B and 260C. The encapsulation layer 420 may include a polymer organic material, for example, an epoxy-based material.

In some embodiments, the filler layer 430 is arranged over the encapsulation layer 420, and a lower surface of the filler layer 430 is substantially conformal with a non-flat upper surface of the encapsulation layer 420. The filler layer 430 may also be referred to as a flat layer. The filler layer 430 may include a polymer organic material, for example, an epoxy-based material. An upper surface of the filler layer 430 may provide a flat surface.

In some embodiments, the cover plate 440 is arranged over a flat upper surface of the filler layer 430. The cover plate 440 may also be referred to as a protective layer. The cover plate 440 may include a transparent hard cover plate, for example, a glass plate. The cover plate 440 may be used to prevent components of the organic light-emitting element from coming into contact with external moisture and hence from malfunctions and light emission failures of the components.

Moreover, according to an embodiment of the present disclosure, the organic light-emitting element 10A further includes a lens located on an optical path between an organic light-emitting layer and a light exiting surface of an organic light-emitting unit, enabling the organic light-emitting unit to generate a collimated light beam.

In some embodiments, the organic light-emitting element 10A further includes the lens structure 60. In some embodiments, the lens structure 60 includes a base material 600, and multiple lenses 610, 620 and 630 protruding from the base material 600. The lenses 610, 620 and 630 are arranged to correspond to the organic light-emitting layers 260A, 260B and 260C, respectively. In some embodiments, the base material 600 is a continuous light transmissive material layer, and the lenses 610, 620 and 630 on the base material 600 are arranged at an appropriate interval. Spaces between adjacent lenses 610, 620 and 630 are non-lens regions 640. In some embodiments, a non-light transmissive object (for example, a black body) may be arranged or a non-light transmissive material (for example, a black material) (not shown) may be added in the non-lens regions 640 to prevent crosstalk of light emitted by the organic light-emitting units 101, 102 and 103.

In some embodiments, by using the lenses 610, 620 and 630, distances between the organic light-emitting layers 260A, 260B and 260C and the organic light-emitting units 101, 102 and 103 may be adjusted to be similar to or equal to focal lengths of the lenses 610, 620 and 630, so that the organic light-emitting units 101, 102 and 103 are located on the focuses of the lenses 610, 620 and 630 to generate collimated light beams. The lenses 610, 620 and 630 may also be referred to as optical collimating lenses.

In some embodiments, the lenses 610, 620 and 630 may be located between the organic light-emitting layers 260A, 260B and 260C and a light exiting surface (for example, the surface 440a of the cover plate 440). In some embodiments, the lenses 610, 620 and 630 are located between the electrode 216 and the cover plate 440, for example, located within the filler layer 430. Sizes of the lenses 610, 620 and 630 may be greater than or equal to sizes of light-emitting pixels, and shapes of the lenses 610, 620 and 630 may be similar to or the same as shapes of the light-emitting pixels. In some embodiments, the sizes of the lenses 610, 620 and 630 are greater than or equal to the sizes of the organic light-emitting layers 260A, 260B and 260C. In some embodiments, the shapes of the lenses 610, 620 and 630 are similar to or the same as the shapes of the organic light-emitting layers 260A, 260B and 260C. In some embodiments, the lenses 610, 620 and 630 correspond to positions of the light-emitting pixels and may be formed in an arrangement corresponding to pixels, and thus may also be referred to as a micro lens array (MLA).

In some embodiments, the lens 610 is located between the electrode 216 and a light exiting surface (for example, the surface 440a of the cover plate 440), for example, buried in the filler layer 430. The lens 610 corresponds to the position above the electrode 215 and the organic light-emitting layer 260A for the organic light-emitting unit 101 to generate a collimated light beam. In some embodiments, a convex surface 610P (or a curved surface) of the lens 610 faces the organic light-emitting layer 260A. In some embodiments, the lens 610 protruding from the base material 600 has a bottom width W1 and a maximum vertical height H1. The maximum vertical height H1 is a maximum vertical distance measured between a highest point of the convex surface 610P (or the curved surface) and the base material 600.

In some embodiments, the lens 620 is located between the electrode 216 and a light exiting surface (for example, the surface 440a of the cover plate 440), for example, buried in the filler layer 430. The lens 620 corresponds to the position above the electrode 225 and the organic light-emitting layer 260B for the organic light-emitting unit 102 to generate a collimated light beam. In some embodiments, a convex surface 620P (or a curved surface) of the lens 620 faces the organic light-emitting layer 260B. In some embodiments, the lens 620 protruding from the base material 600 has a bottom width W2 and a maximum vertical height H2. The maximum vertical height H2 is a maximum vertical distance measured between a highest point of the convex surface 620P (or the curved surface) and the base material 600.

The size of the lens 620 may be the same as or different from the size of the lens 610. For example, in some embodiments, the bottom width W2 of the lens 620 is the same as or different from the bottom width W1 of the lens 610. In some embodiments, the maximum vertical height H2 of the lens 620 is the same as or different from the maximum vertical height H1 of the lens 610. In some embodiments where the convex surfaces of the lenses 610 and 620 are curved surfaces, a radius of curvature of the lens 620 is the same as or different from a radius of curvature of the lens 610.

In some embodiments, the lens 630 is located between the electrode 216 and a light exiting surface (for example, the surface 440a of the cover plate 440), for example, buried in the filler layer 430. The lens 630 corresponds to the position above the electrode 235 and the organic light-emitting layer 260C for the organic light-emitting unit 103 to generate a collimated light beam. In some embodiments, a convex surface 630P (or a curved surface) of the lens 630 faces the organic light-emitting layer 260C. In some embodiments, the lens 630 protruding from the base material 600 has a bottom width W3 and a maximum vertical height H3. The maximum vertical height H3 is a vertical distance measured between a highest point of the convex surface 630P (or the curved surface) and the base material 600.

The size of the lens 630 may be the same as or different from the sizes of the lenses 620 and 610. For example, in some embodiments, the bottom width W3 of the lens 630 is the same as or different from the bottom width W2 of the lens 620, and the bottom width W3 of the lens 630 is the same as or different from the bottom width W1 of the lens 610. In some embodiments, the maximum vertical height H3 of the lens 630 is the same as or different from the maximum vertical height H2 of the lens 620, and the maximum vertical height H3 of the lens 630 is the same as or different from the maximum vertical height H1 of the lens 610. In some embodiments where the convex surfaces of the lenses 610, 620 and 630 are curved surfaces, a radius of curvature of the lens 630 is the same as or different from the radius of curvature of the lens 620, and the radius of curvature of the lens 630 is the same as or different from the radius of curvature of the lens 610.

According to some embodiments of the present disclosure as shown in FIG. 2A, with the design of arranging the reflectors 281, 282 and 283 on the surfaces of transparent electrodes (as the electrodes 215, 225 and 235 shown in FIG. 2A, as anodes), the reflectances of the anodes may be increased to enhance the intensity of a resonant cavity of the organic light-emitting element 10A, further enhancing the color purity of emitted light as well as reducing the diffusion angle of exiting light.

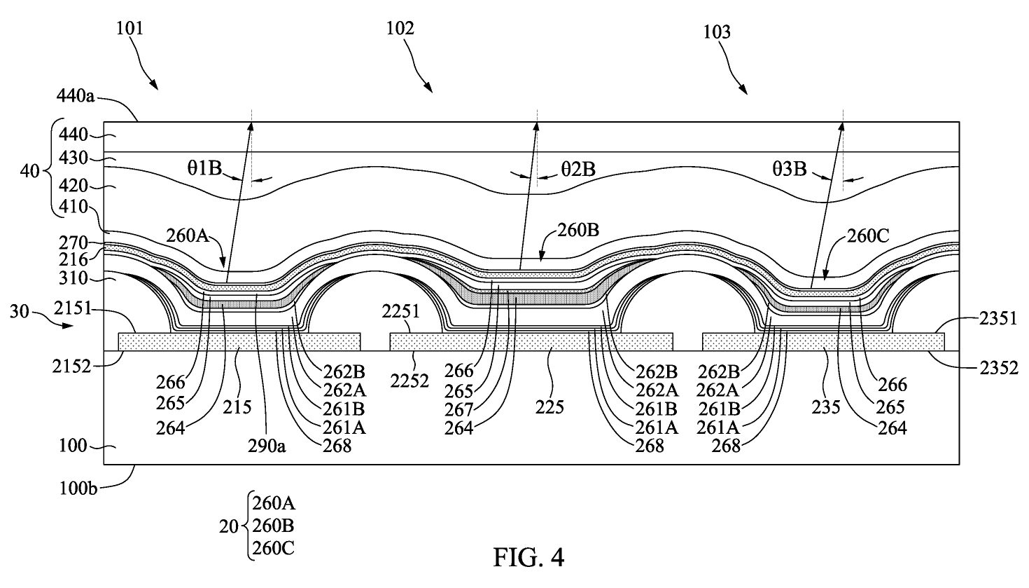

Moreover, refer to FIG. 4 showing a cross-sectional diagram of an organic light-emitting element. Compared with FIG. 2A, FIG. 4 excludes the reflectors 281, 282 and 283 and the lens structure 60, and depicts that light emitted by the organic light-emitting units 101,102 and 103 is at a predetermined angle relative to a normal line of a light exiting surface. This angle varies according to different luminescence wavelengths. In some embodiments, the light emitted from the resonant cavity of the organic light-emitting unit 101 is at an angle θ1B from the normal line of the light exiting surface, the light emitted from the resonant cavity of the organic light-emitting unit 102 is at an angle θ2B from the normal line of the light exiting surface, and the light emitted from the resonant cavity of the organic light-emitting unit 103 is at an angle θ3B from the normal line of the light exiting surface. In some embodiments, at least two of the angle θ1B, the angle θ2B and the angle θ3B are different from each other. According to some embodiments of the present disclosure as shown in FIG. 2A, with the lenses 610, 620 and 630 arranged on optical paths between the organic light-emitting layers 260A, 260B and 260C and a light exiting surface (for example, the surface 440a of the cover plate 440) of the organic light-emitting units 101, 102 and 103, light emitted from the resonant cavities of the organic light-emitting units 101, 102 and 103 passes through the lenses 610, 620 and 630 and is then collimated at the normal line of the light exiting surface (for example, the surface 440a) to generate collimated light beams.

FIG. 2B is a cross-sectional view of an organic light-emitting element 10B. The structure in FIG. 2B is similar to the structure in FIG. 2A, and differences thereof lie in that the lenses 610, 620 and 630 of the lens structure 60 in FIG. 2B have different sizes to correspond to organic light-emitting layers emitting light in different colors.

In some embodiments, the bottom widths W1, W2 and W3 of the lenses 610, 620 and 630 are different. In some embodiments, the maximum vertical heights H1, H2 and H3 of the lenses 610, 620 and 630 are different. In some embodiments where the convex surfaces of the lenses 610, 620 and 630 are curved surfaces, the radii of curvature of the lenses 610, 620 and 630 are different.

In some embodiments, the luminescence wavelength of the organic light-emitting layer 260B is greater than the luminescence wavelength of the organic light-emitting layer 260A, and the luminescence wavelength of the organic light-emitting layer 260A is greater than the luminescence wavelength of the organic light-emitting layer 260C. In some embodiments, the organic light-emitting layer 260A emits green light, the organic light-emitting layer 260B emits red light, and the organic light-emitting layer 260C emits blue light. In some embodiments, the thickness of the organic light-emitting layer 260A, the thickness of the organic light-emitting layer 260B and the thickness of the organic light-emitting layer 260C are different from one another. In some embodiments, the thickness of the organic light-emitting layer 260B (for example, emitting red light) is greater than the thickness of the organic light-emitting layer 260A (for example, emitting green light), and the thickness of the organic light-emitting layer 260A is greater than the thickness of the organic light-emitting layer 260C (for example, emitting blue light). Due to different distances from the organic light-emitting layers 260A, 260B and 260C to the light exiting surface 440a, by designing the sizes of the lenses 610, 620 and 630, respective distances between the organic light-emitting layers 260A, 260B and 260C and the lenses 610, 620 and 630 may be substantially equal.

For example, in some embodiments, the maximum vertical height H1 of the lens 610 above the organic light-emitting layer 260A is greater than the maximum vertical height H2 of the lens 620 above the organic light-emitting layer 260B, and the maximum vertical height H3 of the lens 630 above the organic light-emitting layer 260C is greater than the maximum vertical height H1 of the lens 610 above the organic light-emitting layer 260A (that is, H3>H1>H2). Thus, in some embodiments, the convex surface 630P (or the curved surface) of the lens 630 is closer to a surface 100a of the substrate 100 than the convex surface 610P (or the curved surface) of the lens 610, and the convex surface 610P (or the curved surface) of the lens 610 is closer to the surface 100a of the substrate 100 than the convex surface 620P (or the curved surface) of the lens 620. Moreover, in some embodiments, top surfaces of the organic light-emitting layers 260A, 260B and 260C have vertical distances DL1, DL2 and DL3 from the most protruding points of the convex surfaces 610P, 620P and 630P of the lenses 610, 620 and 630, respectively, and the vertical distances DL1, DL2 and DL3 are substantially equal.

Moreover, in some embodiments, the radius of curvature of the lens 620 above the organic light-emitting layer 260B is greater than the radius of curvature of the lens 610 above the organic light-emitting layer 260A, and the radius of curvature of the lens 610 above the organic light-emitting layer 260A is greater than the radius of curvature of the lens 630 above the organic light-emitting layer 260C, so that distances of the lenses from corresponding organic light-emitting layers are adjusted to enable corresponding organic light-emitting units to generate collimated light beams. Refer to FIG. 2A for description of the remaining components.

FIG. 2C shows a cross-al view of an organic light-emitting element 10C. In some embodiments, FIG. 2C is a cross-sectional view of the organic light-emitting element 10 in FIG. 1. In some embodiments, FIG. 2C is a cross-sectional view taken along the line 1A-1A’ in FIG. 1. In some embodiments, FIG. 2C is a cross-sectional view taken along the line 1A-1A’ in FIG. 1, and only a light-emitting region is illustrated. The structure in FIG. 2C is similar to the structure in FIG. 2A, and differences thereof are described below.

In some embodiments, the organic light-emitting element 10C includes the substrate 100, the electrode 215, the electrode 225, the electrode 235, the electrode 216, the light-emitting layer 20, the inorganic barrier layer 268, a reflector 280, the reflector 281, the reflector 282, the reflector 283, the inorganic barrier layer 270, the spacer structure 30, the cover layer 40 and the lens structure 60. In some embodiments, the electrodes 215, 225, 235 and 216 are transparent electrodes, and for example, include ITO, IZO or other appropriate materials. In some embodiments, reflectors are arranged on outer surfaces of the electrodes 215, 225, 235 and 216 to enhance the reflectance of a transparent electrode.

More specifically, in some embodiments, as shown in FIG. 2C, the reflectors 281, 282 and 283 are arranged over an upper surface (or an outer surface) of the electrode 216, and include the surfaces 281a, 282a and 283a, respectively. In some embodiments, the electrode 216 is in contact with the organic light-emitting layers 260A, 260B and 260C. The electrode 216 may be a continuous film as shown in FIG. 2C and be located above the organic light-emitting layers 260A, 260B and 260C and the protrusions 310.

Moreover, in some embodiments, the reflector 280 is arranged between the electrodes 215, 225 and 235 and the substrate 100. The reflector 280 may be a continuous reflective film as shown in FIG. 2C. In some other embodiments, the reflectors 281, 282 and 283 separated from one another in FIG. 2A may also be used in substitution for the reflector 280 in FIG. 2C.

In some embodiments, for the light emitted by the organic light-emitting layers 260A, 260B and 260C, the reflectance of each of the reflectors 281, 282 and 283 arranged is greater than or equal to 30% (for example, greater than or equal to 30%, greater than or equal to 35%, greater than or equal to 40%, greater than or equal to 45%, greater than or equal to 50%, greater than or equal to 55%, greater than or equal to 60%, greater than or equal to 65%, or greater than or equal to 70%), and for the light emitted by the organic light-emitting layers 260A, 260B and 260C, the reflectance of the reflector 280 arranged is greater than or equal to 80% (for example, greater than or equal to 80%, greater than or equal to 85%, greater than or equal to 90%, or greater than or equal to 95%). In some embodiments, a light exiting surface of the organic light-emitting element 10C is the surface 440a.

In some embodiments, each of the reflectors 280, 281, 282 and 283 includes a reflective metal or a non-conductive reflective material. In some embodiments, each of the reflectors 280, 281, 282 and 283 includes silver, a DBR or other appropriate reflective materials. Each of the reflectors 280, 281, 282 and 283 may include the same material or different materials. In some embodiments where the reflectors 280, 281, 282 and 283 are DBRs, refer to the description of FIG. 2A above for details associated with the DBR as a reflector, and such details are omitted herein.

Moreover, in some embodiments, the reflectors 281, 282 and 283 are non-continuous film layers, and respectively correspond to the position above the organic light-emitting layers 260A, 260B and 260C. Elevations of upper surfaces of the reflectors 281, 282 and 283 are, for example, do not overly protrude from an upper surface of the entire light-emitting layer 20, for example, do not extend above the protrusions 310, and thus the stress brought by the encapsulation layer 420 above the protrusions 310 upon the partial region over the protrusions 310 can be reduced, thereby effectively preventing a portion of the electrode 216 above the protrusions 310 from disconnection due to the stress caused by pressing between materials above (the encapsulation layer 420 and reflectors) and the protrusions 310.

Moreover, in some embodiments, the organic light-emitting element 10C further includes the cover layer 40 and the lens structure 60. The lens structure 60 is buried in the cover layer 40.

In some embodiments, the cover layer 40 includes the capping layer 410, the encapsulation layer 420, the filler layer 430 and the cover plate 440, wherein the filler layer 430 includes a first filler layer 431 and a second filler layer 432. In some embodiments, the lens structure 60 is located over the first filler layer 431, and the second filler layer 432 covers the lens structure 60.

In some embodiments, the capping layer 410 is arranged over the electrode 216, and is substantially conformal with a non-flat upper surface of the electrode 216. The capping layer 410 may include a dielectric material or an inorganic insulating material, for example, SiO₂. In some embodiments, the capping layer 410 may include a hole transport layer material to extract light lost inside the organic light-emitting element so as to improve light-emitting efficiency. The capping layer 410 may also be referred to as a light extraction layer.

In some embodiments, the encapsulation layer 420 is arranged over the capping layer 410, and is substantially conformal with a non-flat upper surface of the capping layer 410. The encapsulation layer 420 may include an oxide, for example, SiO₂. In some embodiments, the encapsulation layer 420 is substantially conformal with the non-flat upper surface of the capping layer 410, and includes a plurality of recesses corresponding to the organic light-emitting layers 260A, 260B and 260C. The encapsulation layer 420 may include a polymer organic material, for example, an epoxy-based material.

In some embodiments, the first filler layer 431 is arranged over the encapsulation layer 420, and a lower surface of the first filler layer 431 is substantially conformal with the non-flat upper surface of the encapsulation layer 420. The first filler layer 431 may also be referred to as a first flat layer. The first filler layer 431 may include a polymer organic material, for example, an epoxy-based material. An upper surface of the first filler layer 431 may provide a flat surface.

In some embodiments, the lens structure 60 is arranged over the flat upper surface of the first filler layer 431, and includes multiple lenses with convex surfaces (or curved surfaces) facing the cover plate 440. In some embodiments, the lens structure 60 includes the base material 600, and the multiple lenses 610, 620 and 630 protruding from the base material 600. In some embodiments, the base material 600 is a continuous light transmissive material layer, and the lenses 610, 620 and 630 on the base material 600 are arranged at an appropriate interval. Spaces between adjacent lenses 610, 620 and 630 are non-lens regions 640. In some embodiments, a non-light transmissive object (for example, a black body) may be arranged or a non-light transmissive material (for example, a black material) (not shown) may be added in the non-lens regions 640 to prevent crosstalk of light emitted by the organic light-emitting units 101, 102 and 103.

In some embodiments, by using the lenses 610, 620 and 630, distances between the organic light-emitting layers 260A, 260B and 260C and the organic light-emitting units 101, 102 and 103 may be adjusted to be similar to or equal to focal lengths of the lenses 610, 620 and 630, so that the organic light-emitting units 101, 102 and 103 are located on the focuses of the lenses 610, 620 and 630 to generate collimated light beams. The lenses 610, 620 and 630 may also be referred to as optical collimating lenses.

In some embodiments, the lenses 610, 620 and 630 may be located between the organic light-emitting layers 260A, 260B and 260C and a light exiting surface (for example, the surface 440a of the cover plate 440). In some embodiments, the lenses 610, 620 and 630 are arranged over the first filler layer 431, and the second filler layer 432 covers the lenses 610, 620 and 630 and provides a flat upper surface. In some embodiments, the second filler layer 432 includes a polymer organic material. In some embodiments, the second filler layer 432 and the first filler layer 431 include different materials or the same material, for example, both including an epoxy-based material.

In some embodiments, the lens 610 corresponds to the position above the electrode 215 and the organic light-emitting layer 260A for the organic light-emitting unit 101 to generate a collimated light beam, the lens 620 corresponds to the position above the electrode 225 and the organic light-emitting layer 260B for the organic light-emitting unit 102 to generate a collimated light beam, and the lens 630 corresponds to the position above the electrode 235 and the organic light-emitting layer 260C for the organic light-emitting unit 103 to generate a collimated light beam.

In some embodiments, the convex surface 610P (or the curved surface) of the lens 610 faces a light exiting surface (for example, the surface 440a of the cover plate 440). In some embodiments, the lens 610 protruding from the base material 600 has the bottom width W1 and the maximum vertical height H1. The maximum vertical height H1 is a maximum vertical distance measured between a highest point of the convex surface 610P (or the curved surface) and the base material 600.

In some embodiments, the convex surface 620P (or the curved surface) of the lens 620 faces a light exiting surface (for example, the surface 440a of the cover plate 440). In some embodiments, the lens 620 protruding from the base material 600 has the bottom width W2 and the maximum vertical height H2. The maximum vertical height H2 is a maximum vertical distance measured between a highest point of the convex surface 620P (or the curved surface) and the base material 600. Moreover, in some embodiments, the bottom width W2 of the lens 620 is the same as or different from the bottom width W1 of the lens 610. In some embodiments, the maximum vertical height H2 of the lens 620 is the same as or different from the maximum vertical height H1 of the lens 610. In some embodiments where the convex surfaces of the lenses 610 and 620 are curved surfaces, the radius of curvature of the lens 620 is the same as or different from the radius of curvature of the lens 610.

In some embodiments, the convex surface 630P (or the curved surface) of the lens 630 faces a light exiting surface (for example, the surface 440a of the cover plate 440). In some embodiments, the lens 630 protruding from the base material 600 has the bottom width W3 and the maximum vertical height H3. The maximum vertical height H3 is a vertical distance measured between a highest point of the convex surface 630P (or the curved surface) and the base material 600. Moreover, in some embodiments, the bottom width W3 of the lens 630 is the same as or different from the bottom width W2 of the lens 620, and the bottom width W3 of the lens 630 is the same as or different from the bottom width W1 of the lens 610. In some embodiments, the maximum vertical height H3 of the lens 630 is the same as or different from the maximum vertical height H2 of the lens 620, and the maximum vertical height H3 of the lens 630 is the same as or different from the maximum vertical height H1 of the lens 610. In some embodiments where the convex surfaces of the lenses 610, 620 and 630 are curved surfaces, the radius of curvature of the lens 630 is the same as or different from the radius of curvature of the lens 620, and the radius of curvature of the lens 630 is the same as or different from the radius of curvature of the lens 610.

In some embodiments, the sizes of the lenses 610, 620 and 630 may be greater than or equal to the sizes of light-emitting pixels, and the shapes of the lenses 610, 620 and 630 may be similar to or the same as the shapes of the light-emitting pixels. In some embodiments, the lenses 610, 620 and 630 correspond to positions of the light-emitting pixels, and may be formed in an arrangement corresponding to pixels to form a micro lens array (MLA).

In some embodiments, after the lens structure 60 is covered by the second filler layer 432, the cover plate 440 is arranged over the flat upper surface of the second filler layer 432. The cover plate 440 may also be referred to as a protective layer. The cover plate 440 may include a transparent hard cover plate, for example, a glass plate. The cover plate 440 may be used to prevent components of the organic light-emitting element from coming into contact with external moisture and hence from malfunction and light emission failures of the components.

According to some embodiments of the present disclosure as shown in FIG. 2C, with the design of arranging the reflectors 280, 281, 282 and 283 on the outer surfaces of transparent electrodes (as shown in FIG. 2C, the electrodes 215, 225 and 235 serving as anodes and the electrode 216 serving as a cathode), the reflectances of the anodes and the cathode may be increased to enhance the intensity of a resonant cavity of the organic light-emitting element 10C, further enhancing the color purity of emitted light as well as reducing the diffusion angle of exiting light.

Moreover, according to some embodiments of the present disclosure as shown in FIG. 2C, with the lenses 610, 620 and 630 arranged on optical paths between the organic light-emitting layers 260A, 260B and 260C and a light exiting surface (for example, the surface 440a of the cover plate 440) of the organic light-emitting units 101, 102 and 103, light emitted from the resonant cavities of the organic light-emitting units 101, 102 and 103 passes through the lenses 610, 620 and 630 and is then collimated at the normal line of the light exiting surface (for example, the surface 440a) to generate collimated light beams. In addition, different from the lens structure 60 in FIG. 2A and FIG. 2B arranged in pairs, the lens structure 60 shown in FIG. 2C is arranged over the first filler layer 431 and is integrally located within the cover layer 40.

FIG. 2D shows a cross-sectional view of an organic light-emitting element 10D. The structure in FIG. 2D is similar to the structure in FIG. 2C, and differences thereof lie in that the lenses 610, 620 and 630 of the lens structure 60 in FIG. 2D have different sizes to correspond to organic light-emitting layers emitting light in different colors.

In some embodiments, the bottom widths W1, W2 and W3 of the lenses 610, 620 and 630 are different. In some embodiments, the maximum vertical heights H1, H2 and H3 of the lenses 610, 620 and 630 are different. In some embodiments where the convex surfaces of the lenses 610, 610 and 620 are curved surfaces, the radii of curvature of the lenses 610, 620 and 630 are different.

In some embodiments, the luminescence wavelength of the organic light-emitting layer 260B is greater than the luminescence wavelength of the organic light-emitting layer 260A, and the luminescence wavelength of the organic light-emitting layer 260A is greater than the luminescence wavelength of the organic light-emitting layer 260C. In some embodiments, the organic light-emitting layer 260A emits green light, the organic light-emitting layer 260B emits red light, and the organic light-emitting layer 260C emits blue light.

In some embodiments, the thickness of the organic light-emitting layer 260A, the thickness of the organic light-emitting layer 260B and the thickness of the organic light-emitting layer 260C are different from one another. In some embodiments, the thickness of the organic light-emitting layer 260B (for example, emitting red light) is greater than the thickness of the organic light-emitting layer 260A (for example, emitting green light), and the thickness of the organic light-emitting layer 260A is greater than the thickness of the organic light-emitting layer 260C (for example, emitting blue light). Thus, distances of the organic light-emitting layers 260A, 260B and 260C to the light exiting surface 440a are all different.

In some embodiments, with the different radii of curvature of the lenses 610, 620 and 630, the organic light-emitting units 101, 102 and 103 are on the focuses of the lenses 610, 620 and 630 to enable corresponding organic light-emitting units to generate collimated light beams. In some embodiments, the radius of curvature of the lens 620 above the organic light-emitting layer 260B is greater than the radius of curvature of the lens 610 above the organic light-emitting layer 260A, and the radius of curvature of the lens 610 above the organic light-emitting layer 260A is greater than the radius of curvature of the lens 630 above the organic light-emitting layer 260C.

In some embodiments, the maximum vertical height H1 of the lens 610 above the organic light-emitting layer 260A is greater than the maximum vertical height H2 of the lens 620 above the organic light-emitting layer 260B, and the maximum vertical height H3 of the lens 630 above the organic light-emitting layer 260C is greater than the maximum vertical height H1 of the lens 610 above the organic light-emitting layer 260A (that is, H3>H1>H2). Thus, in some embodiments, the convex surface 630P (or the curved surface) of the lens 630 is closer to the cover plate 440 than the convex surface 610P (or the curved surface) of the lens 610, and the convex surface 610P (or the curved surface) of the lens 610 is closer to the cover plate 440 than the convex surface 620P (or the curved surface) of the lens 620.

According to some embodiments of the present disclosure as shown in FIG. 2D, with the design of arranging the reflectors 280, 281, 282 and 283 on the outer surfaces of transparent electrodes (as the electrodes 215, 225 and 235 serving as anodes and the electrode 216 serving as a cathode), the reflectances of the anodes and the cathode may be increased to enhance the intensity of a resonant cavity of the organic light-emitting element 10D, further enhancing the color purity of emitted light as well as reducing the diffusion angle of exiting light. Moreover, with the lenses 610, 620 and 630 arranged, light emitted from resonant cavities of the organic light-emitting units 101, 102 and 103 may pass through the lenses 610, 620 and 630 to generate collimated light beams. Refer to FIG. 2C for description of the remaining components.

FIG. 3A to FIG. 3G depict a manufacturing method of the organic light-emitting element 10A (FIG. 2A) according to some embodiments.

As shown in FIG. 3A, in some embodiments, the substrate 100 is provided, the reflectors 281, 282 and 283 are arranged over the substrate 100, the plurality of electrodes 215, 225 and 235 are arranged to form the plurality of protrusions 310 (or the spacer structure 30), wherein each of the protrusions 310 fills a gap between the adjacent electrodes 215, 225 and 235. In some embodiments, the electrodes 215, 225 and 235 are made of a transparent conductive material.

Next, in some embodiments, the inorganic barrier layer 268, the hole injection layer (HIL) 261A, the hole injection layer (HIL) 261B, the hole transport layer (HTL) 262A and the hole transport layer (HTL) 262B are arranged over surfaces of the protrusions 310 and the electrodes 215, 225 and 235. In some embodiments, the inorganic barrier layer 268, the hole injection layer 261A, the hole injection layer 261B, the hole transport layer 262A and the hole transport layer 262B are formed by means of evaporation. In some embodiments, the inorganic barrier layer 268, the hole injection layer 261A, the hole injection layer 261B, the hole transport layer 262A and the hole transport layer 262B may completely undergo the evaporation above the electrodes 215, 225 and 235. Due to smaller thicknesses of the inorganic barrier layer 268, the hole injection layer 261A, the hole injection layer 261B and the hole transport layer 262B, these layers above each of the electrodes 215, 225 and 235 are disconnected from one another via the protrusions 310. Due to a greater thickness of the hole transport layer 262A, the hole transport layer 262A formed continuously extends over the electrodes 215, 225 and 235 and the protrusions 310.

As shown in FIG. 3B, in some embodiments, a buffer layer 301 is arranged over the protrusions 310, and the buffer layer 301 also covers the inorganic barrier layer 268, the hole injection layer 261A, the hole injection layer 261B, the hole transport layer 262A, the hole transport layer 262B, and the electrodes 215, 225 and 235. The buffer layer 301 is for blocking moisture from passing through or entering the protrusions 310, the inorganic barrier layer 268, the hole injection layer 261A, the hole injection layer 261B, the hole transport layer 262A and the hole transport layer 262B. Next, in some embodiments, a photosensitive layer 302 is arranged over the buffer layer 301, wherein the buffer layer 301 and the photosensitive layer 302 are formed by means of coating.

Next, in some embodiments, the photosensitive layer 302 is patterned by a lithography process, such that a portion of the buffer layer 301 is exposed through a groove 314. Next, a portion of the buffer layer 301 is removed (for example, removing by means of a wet etching process) to form a groove 313, so as to expose the hole transport layer 262B.

As shown in FIG. 3C, in some embodiments, an organic emissive layer (EML) 264 is arranged over the hole transport layer 262B, and an electron transport layer (ETL) 265 is arranged over the organic emissive layer (EML) 264. In some embodiments, the organic emissive layer 264 and the electron transport layer 265 are formed by means of evaporation.

As shown in FIG. 3D, in some embodiments, the buffer layer 301, the photosensitive layer 302, and portions of the organic emissive layer 264 and the electron transport layer 265 above the photosensitive layer 302 are removed. In some embodiments, the buffer layer 301, the photosensitive layer 302, and the portions of the organic emissive layer 264 and the electron transport layer 265 are removed by means of a wet etching process. In some embodiments, the steps in FIG. 3B and FIG. 3C are repeated to form the organic emissive layer 264, the hole blocking layer (HBL) 267 and the electron transport layer 265 over the electrode 225, and the organic emissive layer 264 and the electron transport layer 265 are formed over the electrode 235.

As shown in FIG. 3E, in some embodiments, the electron injection layer (EIL) 266 is arranged over the protrusions 310 and the electron transport layer 265. Up to this point, organic light-emitting layers 260A, 260B and 260C (or a light-emitting layer 20) are formed. Next, in some embodiments, the electrode 216 is arranged over the organic light-emitting layers 260A, 260B and 260C and the spacer structure 30. In some embodiments, the electrode 216 is made of a transparent conductive material.

Next, in some embodiments, the reflectors 281, 282 and 283 are arranged above the electrode 216. In some embodiments, the reflectors 281, 282 and 283 respectively have the surfaces 281a, 282a and 283a in contact with the electrode 216. In some embodiments, the reflectors 281, 282 and 283 respectively correspond to the positions above the organic light-emitting layers 260A, 260B and 260C. Next, in some embodiments, the inorganic barrier layer 270 is arranged above the electrode 216, and the inorganic barrier layer 270 covers the reflectors 281, 282 and 283. Up to this point, the organic light-emitting units 101, 102 and 103 are formed.

As shown in FIG. 3F, in some embodiments, the capping layer 410 is arranged over the inorganic barrier layer 270 (for example, by means of evaporation). Next, in some embodiments, the encapsulation layer 420 is arranged over the capping layer 410. In some embodiments, the encapsulation layer 420 is formed by means of plasma-enhanced chemical vapor deposition (PECVD). Next, in some embodiments, the filler layer 430 is arranged over the encapsulation layer 420. The filler layer 430 may fill the recesses of the encapsulation layer 420 and provide a flat surface.

In some embodiments, the cover plate 440 is provided, and the lens structure 60 is arranged on a surface 440b of the cover plate 440 (for example, by means of adhering). In some embodiments, the lens structure 60 includes the base material 600, and multiple lenses 610, 620 and 630 protruding from the base material 600.

Next, as shown in FIG. 3G, in some embodiments, the cover plate 440 arranged with the lens structure 60 is paired with the filler layer 430, such that the lenses 610, 620 and 630 are buried in the filler layer 430 and the cover plate 440 is arranged over the filler layer 430. Up to this point, the organic light-emitting element 10A shown in FIG. 2A is formed.

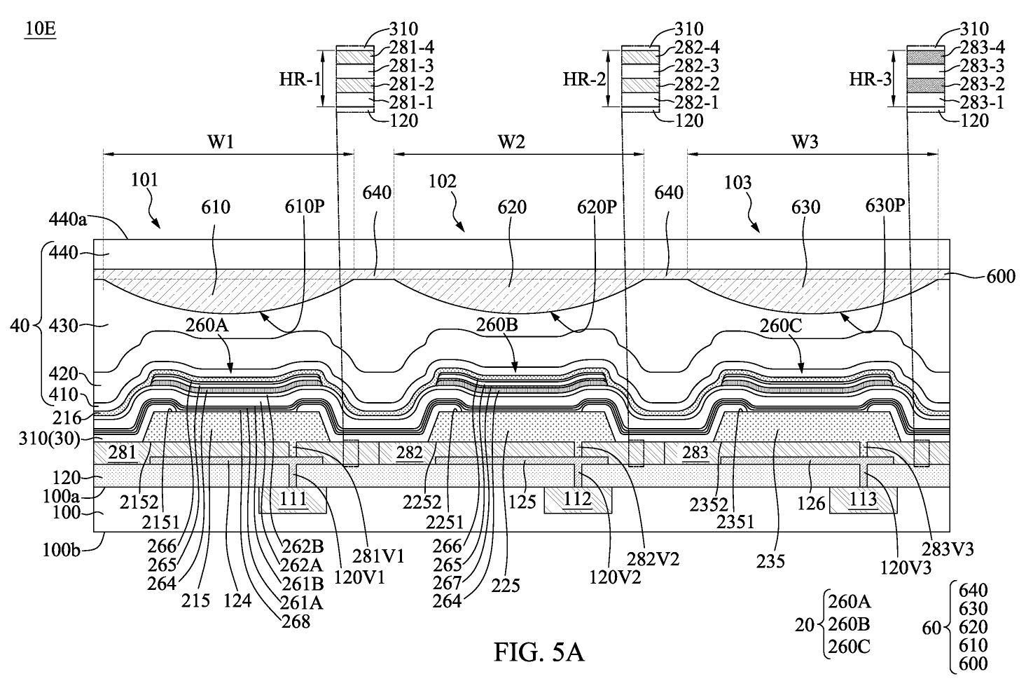

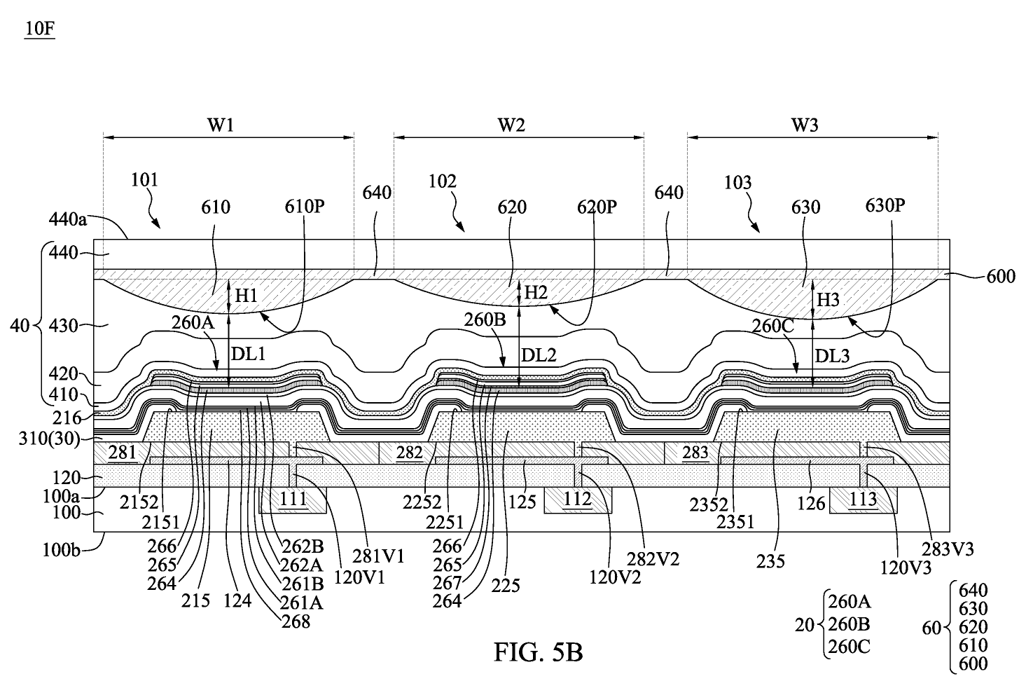

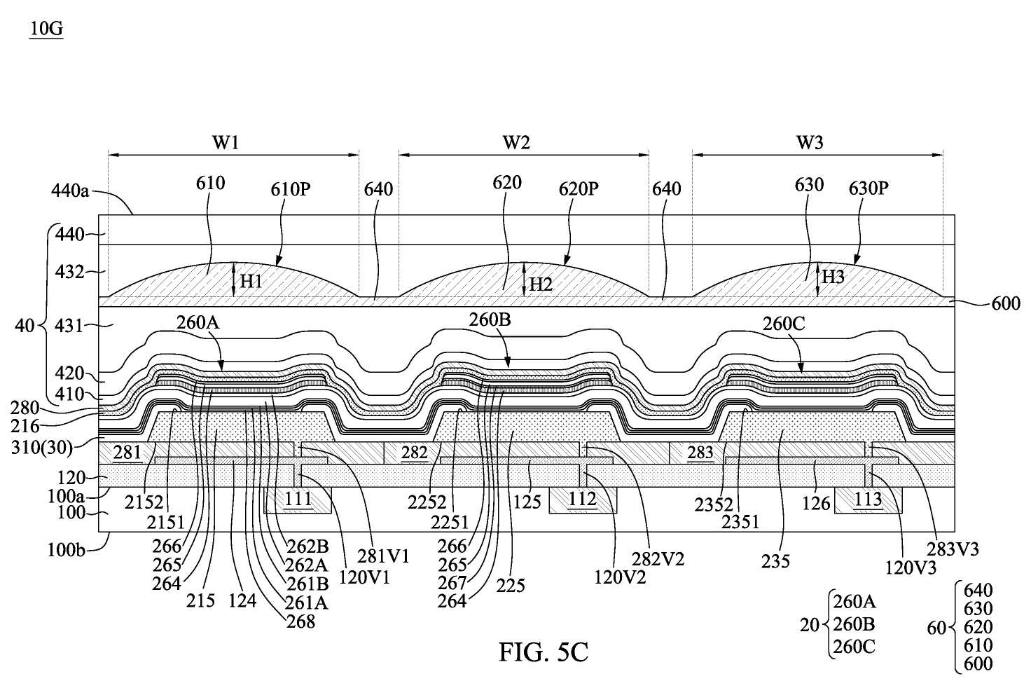

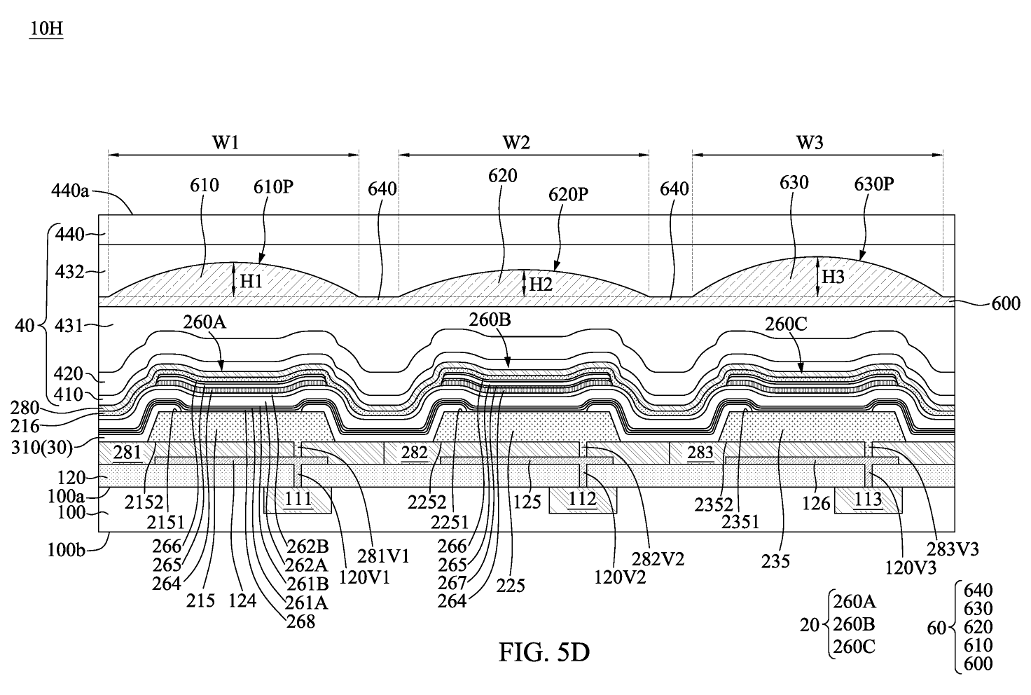

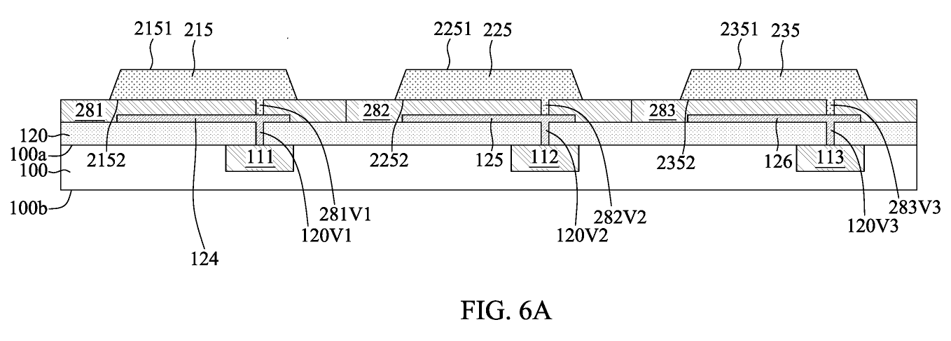

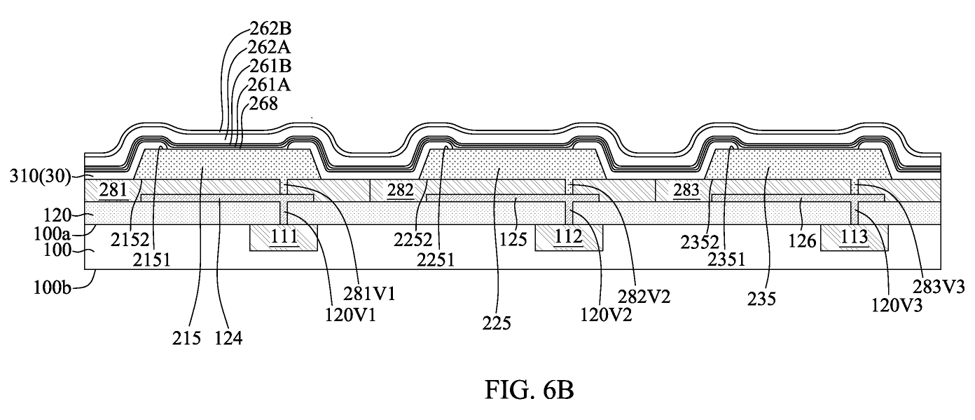

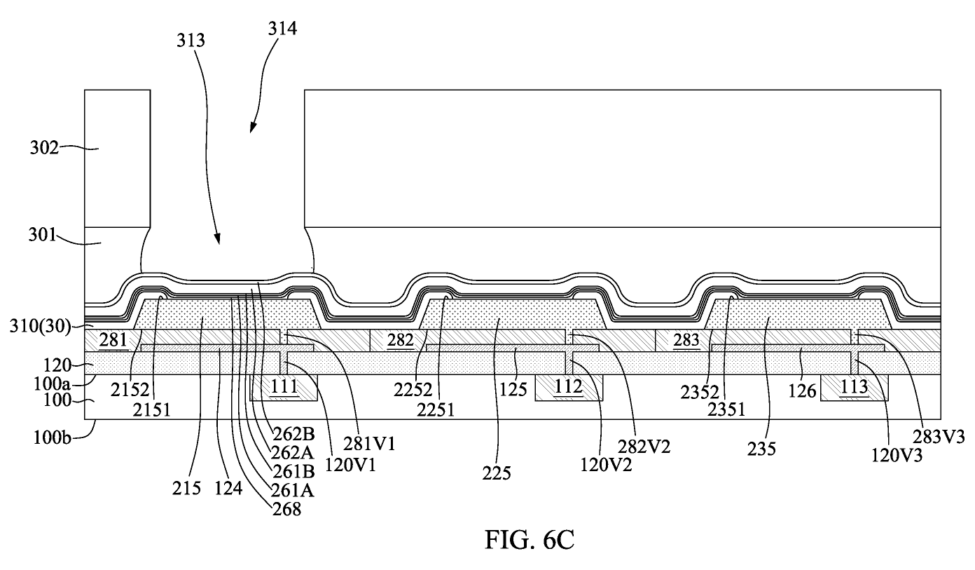

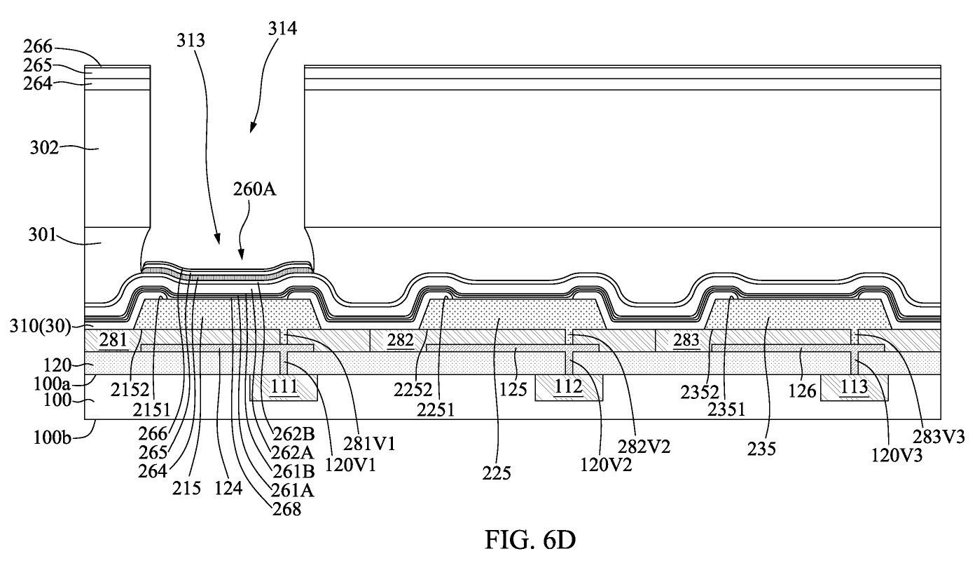

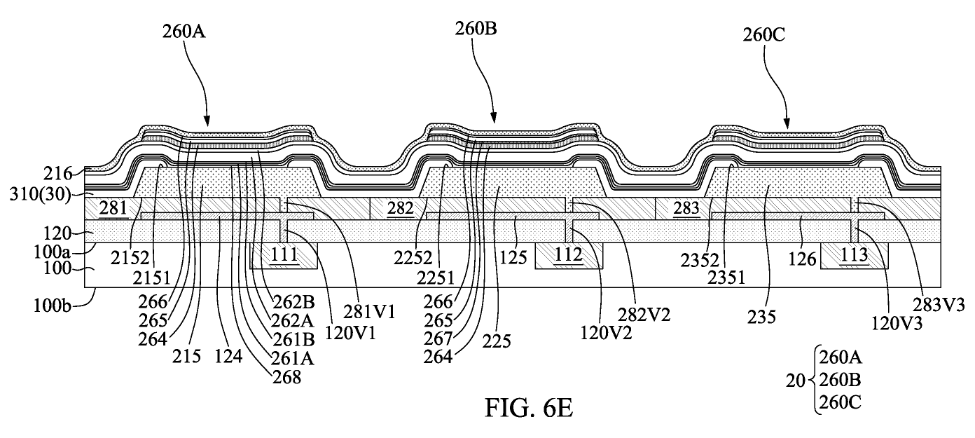

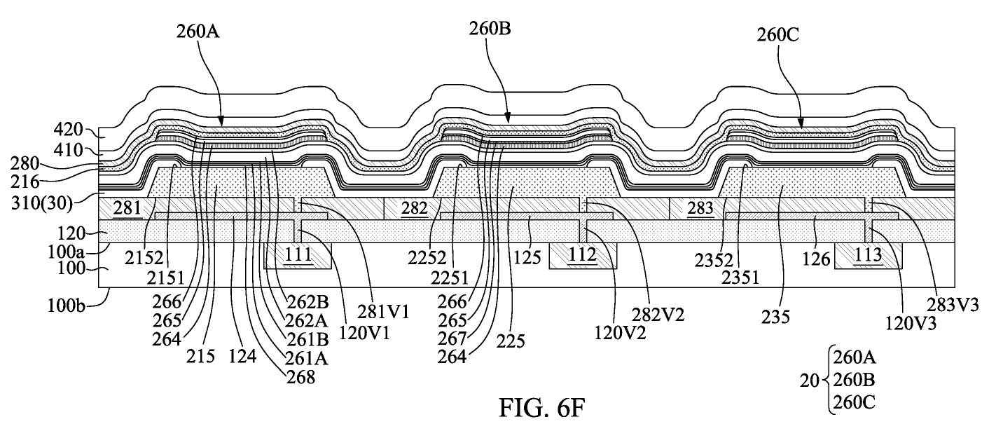

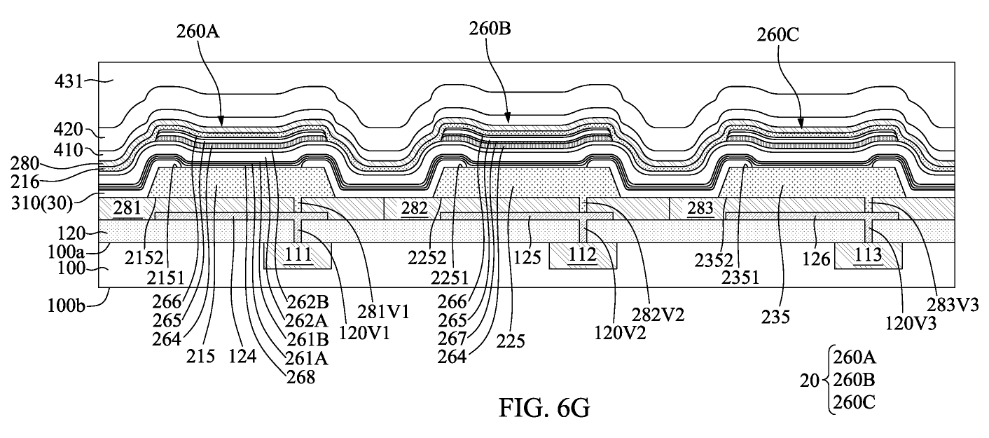

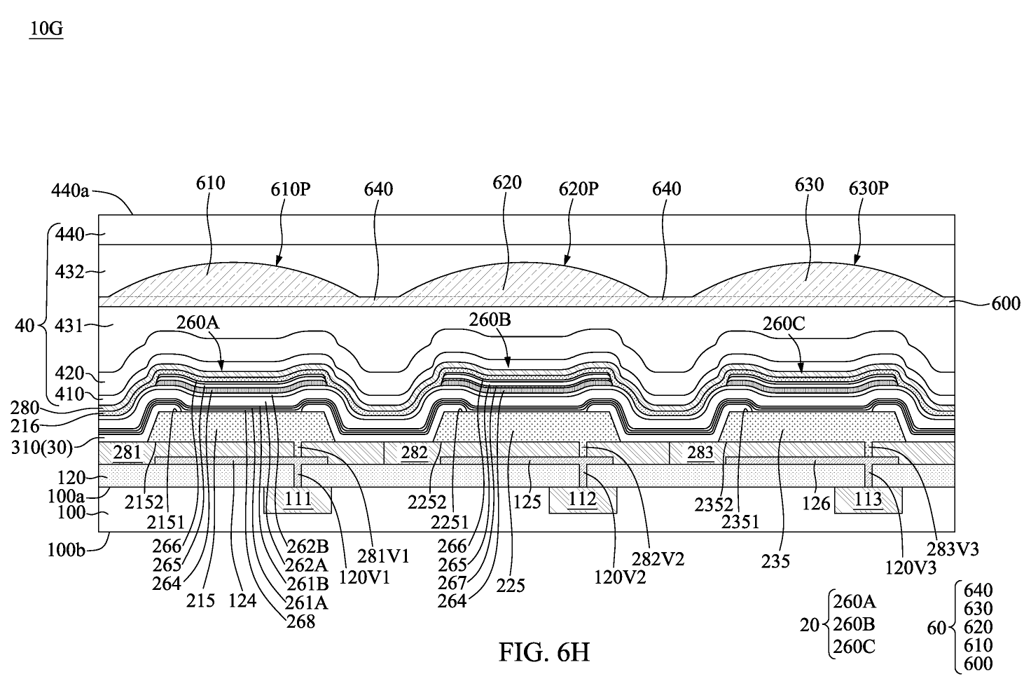

In some embodiments as examples in the description above, the spacer structure 30 includes protrusions made of an organic insulating material; however, the present disclosure is not limited to such example. In some embodiments, the spacer structure 30 may include an inorganic insulating material made into an inorganic insulating film. The inorganic insulating film may serve as a pixel defined layer 310. Thus, in some embodiments as shown in FIG. 5A to FIG. 5D and FIG. 6A to FIG. 6G, the inorganic insulating film may be referred to as an inorganic insulating film 310 for representing the pixel defined layer (PDL) 310 to define a pixel region of an organic light-emitting element of some embodiments.

FIG. 5A is a cross-sectional view of an organic light-emitting element 10E. In some embodiments, FIG. 5A is a cross-sectional view taken along the line 1A-1A’ in FIG. 1. In some embodiments, FIG. 5A is a cross-sectional view taken along the line 1A-1A’ in FIG. 1, and only a light-emitting region is illustrated. The spacer structure 30 includes the pixel defined layers 310 to define a light-emitting pixel pattern. A space for accommodating light-emitting pixels is provided between two adjacent pixel defined layers 310. When viewing the cross-sectional diagram shown in FIG. 5A, a person skilled in the art would be able to understand that the pixel defined layers 310 are depicted in a disconnected manner. However, when viewing the schematic top view of FIG. 1, they can be connected to one another by other parts of the spacer structure 30.

In some embodiments, each of the pixel defined layers 310 fills a gap between two adjacent ones of the electrodes 215, 225 and 235. In some embodiments, the spacer structure 30 may include an inorganic insulating material. In some embodiments, the spacer structure 30 may further include a carbon black material, for example, carbon black nanoparticles, conductive fibers containing carbon black, or the like. In some embodiments, the spacer structure 30 may further include a blackbody material, which has an absorption rate of greater than or equal to 90%, 95%, 99%, 99.5%, or 99.9% for visible light.

In some embodiments, for a specific wavelength, the spacer structure 30 including an inorganic insulating material has an absorption rate of greater than or equal to 50%, greater than or equal to 60%, greater than or equal to 70%, greater than or equal to 80%, greater than or equal to 90%, or greater than or equal to 95%. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

As shown in FIG. 5A, in some embodiments, the organic light-emitting element 10E, for example, includes a plurality of organic light-emitting units (or referred to as light-emitting pixels), for example, including at least the organic light-emitting unit 101 (or referred to as the first organic light-emitting unit), the organic light-emitting unit 102 (or referred to as the second organic light-emitting unit), and the organic light-emitting unit 103 (or referred to as the third organic light-emitting unit). In some embodiments, the organic light-emitting units 101, 102 and 103 are between the pixel defined layers 310 and above the substrate 100. The organic light-emitting units 101, 102 and 103 may emit light having the same wavelength or light having different wavelengths.

In some embodiments, the organic light-emitting element 10E includes the substrate 100, the electrode 215, the electrode 225, the electrode 235, the electrode 216, the light-emitting layer 20, the inorganic barrier layer 268, the reflector 281, the reflector 282, the reflector 283, the inorganic barrier layer 270, the spacer structure 30, the cover layer 40 and the lens structure 60.

In some embodiments, the substrate 100 may include silicon or other appropriate materials. In some embodiments, the substrate 100 may include a silicon substrate and an insulating layer 120 located above the silicon substrate, for example but not limited to, a silicon dioxide layer. In some embodiments, the substrate 100 may include a transistor array, which is configured to correspond to light-emitting pixels in the light-emitting layer 20. The substrate 100 may include a plurality of capacitors. In some embodiments, more than one transistor is configured with one capacitor and one light-emitting pixel to form a circuit. For example, a circuit 111, a circuit 112 and a circuit 113 respectively correspond to the organic light-emitting unit 101, the organic light-emitting unit 102 and the organic light-emitting unit 103.

In some embodiments, the electrodes 215, the electrode 225 and the electrode 235 are located over the substrate 100. In some embodiments, the electrodes 215, 225 and 235 are anodes. The electrodes 215, 225 and 235 may also be referred to as bottom electrodes of the organic light-emitting element 10E. In some embodiments, the electrodes 215, 225 and 235 include a metal material, for example, Ag, Al, Mg, Au, AlCu alloy or AgMo alloy. In some embodiments, the electrodes 215, 225 and 235 include indium tin oxide (ITO), indium zinc oxide (IZO) or other appropriate materials. In some embodiments, materials of the electrode 215, the electrode 225 and the electrode 235 pass through through holes of the insulating layer 120 (for example, a silicon dioxide layer) to form vias 120V1, 120V2 and 120V3, and become electrically connected with the circuit 111, the circuit 112 and the circuit 113 in the substrate 100, respectively. In some embodiments, the pixel defined layers 310 cover portions of upper surfaces of the electrode 215, the electrode 225 and the electrode 235.

In some embodiments, the light-emitting layer 20 includes the organic light-emitting layers 260A, 260B and 260C. In some embodiments, the organic light-emitting layers 260A, 260B and 260C are located over the electrodes 215, 225 and 235, respectively. In some embodiments, the thicknesses of the organic light-emitting layers 260A, 260B and 260C are different from one another. In some embodiments, the thickness of the organic light-emitting layer 260B is greater than the thickness of the organic light-emitting layer 260A, and the thickness of the organic light-emitting layer 260A is greater than the thickness of the organic light-emitting layer 260C.

In some embodiments, the organic light-emitting layers 260A, 260B and 260C emit light having the same color or different colors. In some embodiments, the luminescence wavelength of the organic light-emitting layer 260B is greater than the luminescence wavelength of the organic light-emitting layer 260A, and the luminescence wavelength of the organic light-emitting layer 260A is greater than the luminescence wavelength of the organic light-emitting layer 260C. In some embodiments, the organic light-emitting layer 260A emits green light, the organic light-emitting layer 260B emits red light, and the organic light-emitting layer 260C emits blue light. Refer to details of the description above (for example, the embodiment in FIG. 2A) regarding the materials of the organic light-emitting layers 260A, 260B and 260C and the absorption rates thereof for specific wavelengths.

As shown in FIG. 5A, in some embodiments, the organic light-emitting unit 101 includes the electrode 215, the organic light-emitting layer 260A, and the electrode 216. The electrode 216 may also be referred to as a top electrode of the organic light-emitting element. In some embodiments, the organic light-emitting layer 260A includes multiple organic material layers, for example, the hole injection layer (HIL) 261A, the hole injection layer (HIL) 261B, the hole transport layer (HTL) 262A, the hole transport layer (HTL) 262B, the organic emissive layer (EML) 264, the electron transport layer (ETL) 265 and the electron injection layer (EIL) 266. In some embodiments, the electrode 216 is located above the organic light-emitting layer 260A.

As shown in FIG. 5A, in some embodiments, the organic light-emitting unit 102 includes the electrode 225, the organic light-emitting layer 260B, and the electrode 216. In some embodiments, the organic light-emitting layer 260B includes multiple organic material layers, for example, the hole injection layer (HIL) 261A, the hole injection layer (HIL) 261B, the hole transport layer (HTL) 262A, the hole transport layer (HTL) 262B, the organic emissive layer (EML) 264, the hole blocking layer (HBL) 267, the electron transport layer (ETL) 265 and the electron injection layer (EIL) 266. In some embodiments, the electrode 216 is located above the organic light-emitting layer 260B.

As shown in FIG. 5A, in some embodiments, the organic light-emitting unit 103 includes the electrode 235, the organic light-emitting layer 260C, and the electrode 216. In some embodiments, the organic light-emitting layer 260C includes multiple organic material layers, for example, the hole injection layer (HIL) 261A, the hole injection layer (HIL) 261B, the hole transport layer (HTL) 262A, the hole transport layer (HTL) 262B, the organic emissive layer (EML) 264, the electron transport layer (ETL) 265 and the electron injection layer (EIL) 266. In some embodiments, the electrode 216 is located above the organic light-emitting layer 260C.

As shown in FIG. 5A, a stacked unit of the organic emissive layer (EML) 264, the electron transport layer (ETL) 265 and the electron injection layer (EIL) 266 of the organic light-emitting unit 101 is separated from the organic emissive layer (EML) 264, the hole blocking layer (HBL) 267, the electron transport layer (ETL) 265 and the electron injection layer (EIL) 266 of the organic light-emitting unit 102. The organic emissive layer (EML) 264, the hole blocking layer (HBL) 267, the electron transport layer (ETL) 265 and the electron injection layer (EIL) 266 of the organic light-emitting unit 102 are separated from a stacked unit of the organic emissive layer (EML) 264, the electron transport layer (ETL) 265 and the electron injection layer (EIL) 266 of the organic light-emitting unit 103.

In some embodiments, the organic light-emitting layers 260A, 260B and 260C may have the same thickness or different thicknesses. Moreover, in some embodiments, the organic light-emitting layers 260A, 260B and 260C may be a single-layer light-emitting structure or a cascaded multi-layer light-emitting structure.

In some embodiments, the electrode 216 is in contact with the organic light-emitting layers 260A, 260B and 260C. The electrode 216 may be a continuous film as shown in FIG. 2A and be located above the organic light-emitting layers 260A, 260B and 260C. In some embodiments, the electrode 216 is a common electrode of all light-emitting pixels in the light-emitting layer 20. In some embodiments, the electrode 216 includes a metal material, for example, Ag, Al, Mg, Au, AlCu alloy or AgMo alloy. In some embodiments, the electrode 216 includes, for example, ITO, IZO or other appropriate materials. In other words, the electrode 216 is a common electrode of a plurality of organic light-emitting units. In some embodiments, the electrode 216 is a common electrode of all organic light-emitting units in the organic light-emitting element 10E.

Moreover, in some embodiments, the inorganic barrier layer 268 is located between the electrodes 215, 225 and 235 and the organic light-emitting layers 260A, 260B and 260C. In some embodiments, the inorganic barrier layer 268 substantially completely covers interfaces between the electrodes 215, 225 and 235 and the organic light-emitting layers 260A, 260B and 260C. In some embodiments, the inorganic barrier layer 268 includes a transition metal oxide. In some embodiments, the inorganic barrier layer 268 includes molybdenum oxide (MoO₃). In some embodiments, the inorganic barrier layer 268 and the hole injection layers 261A and 261B may jointly form a hole injection layer of the organic light-emitting layers 260A, 260B and 260C.

According to some embodiments of the present disclosure, the inorganic barrier layer 268 may be used to block metal atoms in the electrodes 215, 225 and 235 from diffusing into the organic light-emitting layers 260A, 260B and 260C (for example, the hole injection layer 261, the hole transport layer 262, the electron barrier layer 263 and the organic emissive layer 264) to avoid quenching, hence preventing degradation of light-emitting efficiency and further enhancing light-emitting luminance and improving a color rendering index (Ra) of an organic light-emitting element. Moreover, according to some embodiments of the present disclosure, the inorganic barrier layer 268 has an extremely small thickness relative to the electrodes 215, 225 and 235, and so the size in thickness of the organic light-emitting element is not significantly increased and an undesirable increase in a light-emitting path is likewise not resulted.

Moreover, according to some embodiments of the present disclosure, the organic light-emitting element further includes the reflectors 281, 282 and 283 to enhance the reflectances of the electrodes 215, 225 and 235 for the light emitted by the organic light-emitting layers 260A, 260B and 260C. In some embodiments, the reflectors 281, 282 and 283 are respectively located between the substrate 100 and the electrodes 215, 225 and 235. In some embodiments, each of the reflectors 281, 282 and 283 includes silver, a DBR or other appropriate reflective materials. Refer to the details provided in the description above (for example, the embodiment in FIG. 2A) regarding the structures and materials of the reflectors 281, 282 and 283. In some embodiments, a light exiting surface of the organic light-emitting element 10E is the surface 440a of the cover plate 440.

Moreover, the organic light-emitting element 10E further includes the cover layer 40 and the lens structure 60. In some embodiments, the cover layer 40 includes the capping layer 410, the encapsulation layer 420, the filler layer 430 and the cover plate 440. In some embodiments, the capping layer 410 is arranged over the electrode 216, and is substantially conformal with a non-flat upper surface of the electrode 216. The capping layer 410 may include a dielectric material or an inorganic insulating material, for example, SiO₂. In some embodiments, the capping layer 410 may include a hole transport layer material to extract light lost inside the organic light-emitting element so as to improve light-emitting efficiency. The capping layer 410 may also be referred to as a light extraction layer.

In some embodiments, the encapsulation layer 420 is arranged over the capping layer 410, and is substantially conformal with a non-flat upper surface of the capping layer 410. The encapsulation layer 420 may include an oxide, for example, SiO₂. In some embodiments, the encapsulation layer 420 is substantially conformal with the non-flat upper surface of the capping layer 410, and includes a plurality of recesses corresponding to positions between the organic light-emitting layers 260A, 260B and 260C. The encapsulation layer 420 may include a polymer organic material, for example, an epoxy-based material.

In some embodiments, the filler layer 430 is arranged over the encapsulation layer 420. A lower surface of the filler layer 430 is substantially conformal with a non-flat upper surface of the encapsulation layer 420, and an upper surface of the filler layer 430 is substantially flat. The filler layer 430 may also be referred to as a flat layer. The filler layer 430 may include a polymer organic material, for example, an epoxy-based material.

In some embodiments, the lens structure 60 includes the base material 600, and multiple lenses 610, 620 and 630 protruding from the base material 600 arranged to correspond to the organic light-emitting layers 260A, 260B and 260C, respectively. The lenses 610, 620 and 630 are located on optical paths between the organic light-emitting layers 260A, 260B and 260C and a light exiting surface (for example, the surface 440a of the cover plate 440) of the organic light-emitting units 101, 102 and 103, enabling the organic light-emitting units 101, 102 and 103 to generate collimated light beams. In some embodiments, the lenses 610, 620 and 630 are buried in the filler layer 430.

In some embodiments, the cover plate 440 is arranged over the flat upper surface of the filler layer 430 and covers the lens structure 60. The cover plate 440 may also be referred to as a protective layer. The cover plate 440 may include a transparent hard cover plate, for example, a glass plate. The cover plate 440 may be used to prevent components of the organic light-emitting element from coming into contact with external moisture and hence from malfunction and light emission failures of the components.

According to some embodiments of the present disclosure as shown in FIG. 5A, with the design of arranging the reflectors 281, 282 and 283 on the surfaces of transparent electrodes (as the electrodes 215, 225 and 235 shown in FIG. 5A, serving as anodes), the reflectances of anodes may be increased to enhance the intensity of a resonant cavity of the organic light-emitting element 10E, further enhancing the color purity of emitted light as well as reducing the diffusion angle of exiting light. Moreover, according to some embodiments of the present disclosure as shown in FIG. 5A, with the lens structure 60 arranged, light emitted from resonant cavities of the organic light-emitting units 101, 102 and 103 may pass through the lenses 610, 620 and 630 and then be collimated at the normal line of the light exiting surface (for example, the surface 440a) to generate collimated light beams.

FIG. 5B is a cross-sectional view of an organic light-emitting element 10F. The structure in FIG. 5B is similar to the structure in FIG. 5A, and differences thereof lie in that the lenses 610, 620 and 630 of the lens structure 60 in FIG. 5B have different sizes to correspond to organic light-emitting layers emitting light in different colors.

In some embodiments, the bottom widths W1, W2 and W3 of the lenses 610, 620 and 630 are different. In some embodiments, the maximum vertical heights H1, H2 and H3 of the lenses 610, 620 and 630 are different. In some embodiments where the convex surfaces of the lenses 610, 620 and 630 are curved surfaces, the radii of curvature of the lenses 610, 620 and 630 are different.

In some embodiments, the luminescence wavelength of the organic light-emitting layer 260B is greater than the luminescence wavelength of the organic light-emitting layer 260A, and the luminescence wavelength of the organic light-emitting layer 260A is greater than the luminescence wavelength of the organic light-emitting layer 260C. In some embodiments, the organic light-emitting layer 260A emits green light, the organic light-emitting layer 260B emits red light, and the organic light-emitting layer 260C emits blue light. In some embodiments, the thickness of the organic light-emitting layer 260A, the thickness of the organic light-emitting layer 260B and the thickness of the organic light-emitting layer 260C are different from one another. In some embodiments, the thickness of the organic light-emitting layer 260B (for example, emitting red light) is greater than the thickness of the organic light-emitting layer 260A (for example, emitting green light), and the thickness of the organic light-emitting layer 260A is greater than the thickness of the organic light-emitting layer 260C (for example, emitting blue light). In some embodiments, the maximum vertical height H1 of the lens 610 above the organic light-emitting layer 260A is greater than the maximum vertical height H2 of the lens 620 above the organic light-emitting layer 260B, and the maximum vertical height H3 of the lens 630 above the organic light-emitting layer 260C is greater than the maximum vertical height H1 of the lens 610 above the organic light-emitting layer 260A (that is, H3>H1>H2). Thus, in some embodiments, the convex surface 630P (or the curved surface) of the lens 630 is closer to the surface 100a of the substrate 100 than the convex surface 610P (or the curved surface) of the lens 610, and the convex surface 610P (or the curved surface) of the lens 610 is closer to the surface 100a of the substrate 100 than the convex surface 620P (or the curved surface) of the lens 620.

Moreover, in some embodiments, the radius of curvature of the lens 620 above the organic light-emitting layer 260B is greater than the radius of curvature of the lens 610 above the organic light-emitting layer 260A, and the radius of curvature of the lens 610 above the organic light-emitting layer 260A is greater than the radius of curvature of the lens 630 above the organic light-emitting layer 260C, so that distances of the lenses from corresponding organic light-emitting layers are adjusted to enable corresponding organic light-emitting units to generate collimated light beams. Refer to FIG. 5A for description of the remaining components.

FIG. 5C shows a cross-sectional view of an organic light-emitting element 10G. In some embodiments, FIG. 5C is a cross-sectional view of the organic light-emitting element 10 in FIG. 1. In some embodiments, FIG. 5C is a cross-sectional view taken along the line 1A-1A’ in FIG. 1. In some embodiments, FIG. 5C is a cross-sectional view taken along the line 1A-1A’ in FIG. 1, and only a light-emitting region is illustrated. The structure in FIG. 5C is similar to the structure in FIG. 5A, and differences thereof are described below.

In some embodiments, the organic light-emitting element 10G includes the substrate 100, the electrode 215, the electrode 225, the electrode 235, the electrode 216, the light-emitting layer 20, the inorganic barrier layer 268, the reflector 280, the reflector 281, the reflector 282, the reflector 283, the spacer structure 30, the cover layer 40 and the lens structure 60. In some embodiments, the electrodes 215, 225, 235 and 216 are transparent electrodes, and for example, include ITO, IZO or other appropriate materials. In some embodiments, reflectors are arranged on outer surfaces of the electrodes 215, 225, 235 and 216 to enhance the reflectance of a transparent electrode. In some embodiments, a light exiting surface of the organic light-emitting element 10G is the surface 440a.

More specifically, in some embodiments, as shown in FIG. 5C, the reflectors 281, 282 and 283 are arranged between the electrodes 215, 225 and 235 and the substrate 100. In some embodiments, the electrode 216 is in contact with the organic light-emitting layers 260A, 260B and 260C. The electrode 216 may be a continuous film as shown in FIG. 5C and be located above the organic light-emitting layers 260A, 260B and 260C and the pixel defined layers 310. Moreover, in some embodiments, the reflector 280 is arranged on an upper surface (or an outer surface) of the electrode 216. The reflector 280 may be a continuous reflective film as shown in FIG. 5C. In some other embodiments, the reflectors 281, 282 and 283 separated from one another in FIG. 2C may also be used in substitution for the reflector 280 in FIG. 5C.

In some embodiments, each of the reflectors 280, 281, 282 and 283 includes silver, a DBR or other appropriate reflective materials. Each of the reflectors 280, 281, 282 and 283 may include the same material or different materials. In some embodiments where the reflectors 280, 281, 282 and 283 are DBRs, refer to the description of FIG. 2A above for details associated with the DBR as a reflector, and such details are omitted herein.

Moreover, in some embodiments, the organic light-emitting element 10G further includes the cover layer 40 and the lens structure 60. The lens structure 60 is buried in the cover layer 40.

In some embodiments, the cover layer 40 includes the capping layer 410, the encapsulation layer 420, the filler layer 430 and the cover plate 440, wherein the filler layer 430 includes the first filler layer 431 and the second filler layer 432. In some embodiments, the lens structure 60 is located over the first filler layer 431, and the second filler layer 432 covers the lens structure 60. Refer to the description above for details of the capping layer 410, the encapsulation layer 420, the filler layer 430 and the cover plate 440, and such details are omitted herein.

In some embodiments, the lens structure 60 is arranged over the flat upper surface of the first filler layer 431, and includes multiple lenses with convex surfaces (or curved surfaces) facing the cover plate 440. In some embodiments, the lens structure 60 includes the base material 600, and the multiple lenses 610, 620 and 630 protruding from the base material 600. In some embodiments, the base material 600 is a continuous light transmissive material layer, and the lenses 610, 620 and 630 on the base material 600 are arranged at an appropriate interval. Spaces between adjacent lenses 610, 620 and 630 are non-lens regions 640. In some embodiments, a non-light transmissive object (for example, a black body) may be arranged or a non-light transmissive material (for example, a black material) (not shown) may be added in the non-lens regions 640 to prevent crosstalk of light emitted by the organic light-emitting units 101, 102 and 103.

In some embodiments, the lenses 610, 620 and 630 may be located between the organic light-emitting layers 260A, 260B and 260C and a light exiting surface (for example, the surface 440a of the cover plate 440), enabling the organic light-emitting units 101, 102 and 103 to generate collimated light beams. In some embodiments, the lenses 610, 620 and 630 are arranged over the first filler layer 431, and the second filler layer 432 covers the lenses 610, 620 and 630 and provides a flat upper surface. In some embodiments, the second filler layer 432 includes a polymer organic material. In some embodiments, the second filler layer 432 and the first filler layer 431 include different materials or the same material, for example, both including an epoxy-based material.

In some embodiments, the convex surface 610P (or the curved surface) of the lens 610 faces a light exiting surface (for example, the surface 440a of the cover plate 440). In some embodiments, the lens 610 protruding from the base material 600 has the bottom width W1 and the maximum vertical height H1. The maximum vertical height H1 is a maximum vertical distance measured between a highest point of the convex surface 610P (or the curved surface) and the base material 600.

In some embodiments, the convex surface 620P (or the curved surface) of the lens 620 faces a light exiting surface (for example, the surface 440a of the cover plate 440). In some embodiments, the lens 620 protruding from the base material 600 has the bottom width W2 and the maximum vertical height H2. The maximum vertical height H2 is a maximum vertical distance measured between a highest point of the convex surface 620P (or the curved surface) and the base material 600. Moreover, in some embodiments, the bottom width W2 of the lens 620 is the same as or different from the bottom width W1 of the lens 610. In some embodiments, the maximum vertical height H2 of the lens 620 is the same as or different from the maximum vertical height H1 of the lens 610. In some embodiments where the convex surfaces of the lenses 610 and 620 are curved surfaces, the radius of curvature of the lens 620 is the same as or different from the radius of curvature of the lens 610.

In some embodiments, the convex surface 630P (or the curved surface) of the lens 630 faces a light exiting surface (for example, the surface 440a of the cover plate 440). In some embodiments, the lens 630 protruding from the base material 600 has the bottom width W3 and the maximum vertical height H3. The maximum vertical height H3 is a vertical distance measured between a highest point of the convex surface 630P (or the curved surface) and the base material 600. Moreover, in some embodiments, the bottom width W3 of the lens 630 is the same as or different from the bottom width W2 of the lens 620, and the bottom width W3 of the lens 630 is the same as or different from the bottom width W1 of the lens 610. In some embodiments, the maximum vertical height H3 of the lens 630 is the same as or different from the maximum vertical height H2 of the lens 620, and the maximum vertical height H3 of the lens 630 is the same as or different from the maximum vertical height H1 of the lens 610. In some embodiments where the convex surfaces of the lenses 610, 620 and 630 are curved surfaces, the radius of curvature of the lens 630 is the same as or different from the radius of curvature of the lens 620, and the radius of curvature of the lens 630 is the same as or different from the radius of curvature of the lens 610.

In some embodiments, the sizes of the lenses 610, 620 and 630 may be greater than or equal to the sizes of light-emitting pixels, and the shapes of the lenses 610, 620 and 630 may be similar to or the same as the shapes of the light-emitting pixels. In some embodiments, the lenses 610, 620 and 630 correspond to positions of the light-emitting pixels, and may be formed in an arrangement corresponding to pixels to form a micro lens array (MLA).

According to some embodiments of the present disclosure as shown in FIG. 5C, with the design of arranging the reflectors 280, 281, 282 and 283 on the surfaces of transparent electrodes (as shown in FIG. 5C, the electrodes 215, 225 and 235 serving as anodes and the electrode 216 serving as a cathode), the reflectances of the anodes and the cathode may be increased to enhance the intensity of a resonant cavity of the organic light-emitting element 10G, further enhancing the color purity of emitted light as well as reducing the diffusion angle of exiting light. Moreover, according to some embodiments of the present disclosure as shown in FIG. 5C, with the lens structure 60 arranged, light emitted from resonant cavities of the organic light-emitting units 101, 102 and 103 may pass through the lenses 610, 620 and 630 and then be collimated at the normal line of the light exiting surface (for example, the surface 440a) to generate collimated light beams.

Different from the lens structure 60 in FIG. 5A and FIG. 5B arranged in pairs, the lens structure 60 shown in FIG. 5C is arranged over the first filler layer 431 and then covered by the second filler layer 432, and thus the lens structure 60 shown in FIG. 5C is integrally arranged within the cover layer 40.

FIG. 5D shows a cross-sectional view of an organic light-emitting element 10H. The structure in FIG. 5D is similar to the structure in FIG. 5C, and differences thereof lie in that the lenses 610, 620 and 630 of the lens structure 60 in FIG. 5D have different sizes to correspond to organic light-emitting layers emitting light in different colors.

As shown in FIG. 5D, in some embodiments, the bottom widths W1, W2 and W3 of the lenses 610, 620 and 630 are different. In some embodiments, the maximum vertical heights H1, H2 and H3 of the lenses 610, 620 and 630 are different. In some embodiments where the convex surfaces of the lenses 610, 620 and 630 are curved surfaces, the radii of curvature of the lenses 610, 620 and 630 are different. Refer to details of the lenses 610, 620 and 630 in FIG. 2D described above for details of the lenses 610, 620 and 630 in FIG. 5D. Refer to the description of FIG. 5A to FIG. 5C described above for details of the remaining components in FIG. 5D.

According to some embodiments of the present disclosure as shown in FIG. 5D, with the design of arranging the reflectors 280, 281, 282 and 283 on the surfaces of transparent electrodes (as shown in FIG. 5D, the electrodes 215, 225 and 235 serving as anodes and the electrode 216 serving as a cathode), the reflectances of the anodes and the cathode may be increased to enhance the intensity of a resonant cavity of the organic light-emitting element 10H, further enhancing the color purity of emitted light as well as reducing the diffusion angle of exiting light. Moreover, according to some embodiments of the present disclosure as shown in FIG. 5D, with the lens structure 60 arranged, light emitted from resonant cavities of the organic light-emitting units 101, 102 and 103 may pass through the lenses 610, 620 and 630 and then be collimated at the normal line of the light exiting surface (for example, the surface 440a) to generate collimated light beams.

FIG. 6A to FIG. 6H depict a manufacturing method of the organic light-emitting element 10G (FIG. 5C) according to some embodiments.

As shown in FIG. 6A, in some embodiments, the substrate 100 is provided, and the circuit 111, the circuit 112 and the circuit 113 are arranged in the substrate 100. In some embodiments, the insulating layer 120 (for example, a silicon dioxide layer) is arranged over the substrate 100, and a conductive layer 124, a conductive layer 125 and a conductive layer 126 are arranged separately over the insulating layer 120. In some embodiments, the insulating layer 120 includes multiple through holes to expose partial surfaces of the circuit 111, the circuit 112 and the circuit 113 below. In some embodiments, a conductive material (for example, metal) is deposited over the insulating layer 120, wherein the conductive material fills the through holes of the insulating layer 120 to connect the circuit 111, the circuit 112 and the circuit 113. Then, the conductive material is patterned to form the conductive layer 124, the conductive layer 125 and the conductive layer 126.

In some embodiments, the reflectors 281, 282 and 283 are arranged over the insulating layer 120, and the electrode 215, the electrode 225 and the electrode 235 are arranged over the reflectors 281, 282 and 283, respectively. The reflectors 281, 282 and 283 cover the insulating layer 120, and correspond to and cover the conductive layer 124, the conductive layer 125 and the conductive layer 126, respectively. Refer to the description with reference to FIG. 5A for details of components and methods for forming the reflectors 281, 282 and 283.

Then, in some embodiments, an electrode material is deposited over the reflectors 281, 282 and 283, wherein the electrode material fills the through holes of the reflectors 281, 282 and 283 to form vias 281V1, 282V2 and 282V3. Then, the electrode material is patterned to form the electrode 215, the electrode 225 and the electrode 235 arranged separately. In some embodiments, the electrodes 215, 225 and 235 may be made of a transparent conductive material.

In some embodiments, the electrode 215 may be connected to the circuit 111 below through the via 281V1, the conductive layer 124 and the via 120V1, the electrode 225 may be connected to the circuit 112 below through the via 282V2, the conductive layer 125 and the via 120V2, and the electrode 235 may be connected to the circuit 113 below through the via 283V3, the conductive layer 126 and the via 120V3.

As shown in FIG. 6B, in some embodiments, the pixel defined layers 310 are formed. Each of the pixel defined layers 310 fills a gap between the adjacent electrodes 215, 225 and 235. In some embodiments, the pixel defined layers 310 are inorganic material layers.

Next, in some embodiments, the inorganic barrier layer 268, the hole injection layer (HIL) 261A, the hole injection layer (HIL) 261B, the hole transport layer (HTL) 262A and the hole transport layer (HTL) 262B are arranged over surfaces of the pixel defined layers 310 and the electrodes 215, 225 and 235. In some embodiments, the inorganic barrier layer 268, the hole injection layer 261A, the hole injection layer 261B, the hole transport layer 262A and the hole transport layer 262B may be formed by means of evaporation completely over the electrodes 215, 225 and 235. In some embodiments, due to a smaller thickness of the pixel defined layers 310, each of the layers above the individual electrodes 215, 225 and 235 is a common layer that extends continuously.

As shown in FIG. 6C, in some embodiments, the buffer layer 301 is arranged over the hole transport layer 262B. Moreover, the buffer layer 301 covers the inorganic barrier layer 268, the hole injection layer 261A, the hole injection layer 261B, the hole transport layer 262A, the hole transport layer 262B, the pixel defined layers 310 and the electrodes 215, 225 and 235. The buffer layer 301 is for blocking moisture from passing through or entering the pixel defined layers 310, the inorganic barrier layer 268, the hole injection layer 261A, the hole injection layer 261B, the hole transport layer 262A and the hole transport layer 262B. Next, in some embodiments, the photosensitive layer 302 is arranged over the buffer layer 301, wherein the buffer layer 301 and the photosensitive layer 302 are formed by means of coating.

Next, in some embodiments, the photosensitive layer 302 is patterned by a lithography process, such that a portion of the buffer layer 301 is exposed through a groove 314. Next, a portion of the buffer layer 301 is removed (for example, removing by means of a wet etching process) to form the groove 313, so as to expose the hole transport layer 262B.

As shown in FIG. 6D, in some embodiments, the organic emissive layer (EML) 264 is arranged over the hole transport layer 262B, the electron transport layer (ETL) 265 is arranged over the organic emissive layer (EML) 264, and the electron injection layer (EIL) 266 is arranged over the electron transport layer 265. In some embodiments, the organic emissive layer 264, the electron transport layer 265 and the electron injection layer 266 are formed by means of evaporation. Up to this point, the organic light-emitting layer 260A is formed.

As shown in FIG. 6E, in some embodiments, the buffer layer 301, the photosensitive layer 302, and portions of the organic emissive layer 264, the electron transport layer 265 and the electron injection layer 266 over the photosensitive layer 302 are removed. In some embodiments, the buffer layer 301, the photosensitive layer 302, and the portions of the organic emissive layer 264, the electron transport layer 265 and the electron injection layer 266 are removed by means of a wet etching process.

In some embodiments, the steps in FIG. 6C and FIG. 6D are repeated to form the organic emissive layer 264, the hole blocking layer (HBL) 267, the electron transport layer 265 and the electron injection layer 266 over the electrode 225, and to form the organic emissive layer 264, the electron transport layer 265 and the electron injection layer 266 over the electrode 235. Up to this point, the organic light-emitting layers 260B and 260C are formed. Next, in some embodiments, the electrode 216 is arranged over the organic light-emitting layers 260A, 260B and 260C. In some embodiments, the electrode 216 is made of a transparent conductive material or thin metal.

Next, as shown in FIG. 6F, the reflector 280 is arranged over the electrode 216. The reflector 280 may be a continuous reflective film as shown in the drawing. Next, in some embodiments, the capping layer 410 is arranged over the reflector 280 (for example, by means of evaporation). Next, in some embodiments, the encapsulation layer 420 is arranged over the capping layer 410. In some embodiments, the encapsulation layer 420 is formed by means of plasma-enhanced chemical vapor deposition (PECVD).

Next, as shown in FIG. 6G, in some embodiments, the first filler layer 431 is arranged over the encapsulation layer 420. The first filler layer 431 may fill the recesses of the encapsulation layer 420 and provide a flat surface. Refer to the description of the embodiments above for details of the components and methods for forming the reflector 280, the capping layer 410, the encapsulation layer 420 and the first filler layer 431.

Next, as shown in FIG. 6H, in some embodiments, the lens structure 60 is arranged over the first filler layer 431. In some embodiments, the lens structure 60 includes the base material 600, and the multiple lenses 610, 620 and 630 protruding from the base material 600. Refer to the description of the embodiments above (for example, FIG. 5C) for details of the structures and methods for forming the lenses 610, 620 and 630. Accordingly, the lens structure 60 can be integrally arranged in the cover layer 40, such that light emitted from resonant cavities of the organic light-emitting units 101, 102 and 103 may pass through the lenses 610, 620 and 630 and then be collimated at the normal line of the light exiting surface (for example, the surface 440a) to generate collimated light beams.

Next, in some embodiments, the second filler layer 432 is arranged over the first filler layer 431, wherein the second filler layer 432 covers the lens structure 60 to fill the recesses between the lenses 610, 620 and 630 and provide a flat surface. Next, the cover plate 440 is arranged over a flat upper surface of the second filler layer 432. As shown in FIG. 6H, up to this point, the organic light-emitting element 10G shown in FIG. 5C is formed.

The features of some embodiments are described briefly above for a person skilled in the art to better understand various aspects of the present disclosure. A person skilled in the art would be able to understand that the present disclosure can be used as the basis for designing or modifying other manufacturing processes and structures so as to achieve the same objects and/or the same advantages of the embodiments described in the present application. A person skilled in the art would also be able to understand that such structures do not depart from the spirit and scope of the disclosure of the present application, and various changes, substitutions and replacements may be made to the embodiments by a person skilled in the art without departing from the spirit and scope of the present disclosure.

What is claimed is:

1. An organic light-emitting element, comprising:
organic light-emitting units, each of the organic light-emitting units comprising:
a substrate;
a first electrode, located over the substrate;
an organic light-emitting layer, located over the first electrode;
a second electrode, located over the organic light-emitting layer, wherein one of the first electrode and the second electrode comprises a transparent conductive material;
a reflector, located on one side of one of the first electrode and the second electrode, the reflector enhancing intensity of a resonant cavity of the organic light-emitting unit; and
a lens, located on an optical path between the organic light-emitting layer and a light exiting surface of the organic light-emitting unit, to enable the organic light-emitting unit to generate a collimated light beam.

2. The organic light-emitting element according to claim 1, wherein the organic light-emitting units comprise:
a first organic light-emitting unit, comprising:
a first organic light-emitting layer, emitting light in a first waveband; and
a first lens, enabling the first organic light-emitting unit to generate the collimated light beam; and
a second organic light-emitting unit, comprising:
a second organic light-emitting layer, emitting light in a second waveband, wherein a wavelength of the light in the second waveband is different from a wavelength of the light in the first waveband; and
a second lens, enabling the second organic light-emitting unit to generate the collimated light beam, wherein a size of the second lens is different from a size of the first lens.

3. The organic light-emitting element according to claim 2, wherein a radius of curvature of the second lens is different from a radius of curvature of the first lens.

4. The organic light-emitting element according to claim 2, wherein a maximum vertical height of the second lens is different from a maximum vertical height of the first lens.

5. The organic light-emitting element according to claim 2, wherein the wavelength of the light in the first waveband is less than the wavelength of the light in the second waveband, and the radius of curvature of the first lens is greater than the radius of curvature of the second lens.

6. The organic light-emitting element according to claim 2, wherein the first organic light-emitting layer has a first thickness, the second organic light-emitting layer has a second thickness, the second thickness is greater than the first thickness, and the maximum vertical height of the second lens is less than the maximum vertical height of the first lens.

7. The organic light-emitting element according to claim 2, wherein the organic light-emitting units comprise:
a third organic light-emitting unit, comprising:
a third organic light-emitting layer, emitting light in a third waveband, wherein a wavelength of the light in the third waveband is different from the wavelength of the light in the first waveband; and
a third lens, enabling the third organic light-emitting unit to generate the collimated light beam, wherein a size of the third lens is different from the size of the first lens and the size of the second lens.

8. The organic light-emitting element according to claim 7, wherein the wavelength of the light in the first waveband is less than the wavelength of the light in the second waveband, and the wavelength of the light in the third waveband is less than the wavelength of the light in the first waveband.

9. The organic light-emitting element according to claim 8, wherein the radius of curvature of the first lens is greater than the radius of curvature of the second lens, and a radius of curvature of the third lens is greater than the radius of curvature of the first lens.

10. The organic light-emitting element according to claim 8, wherein the first organic light-emitting layer has a first thickness, the second organic light-emitting layer has a second thickness, the third organic light-emitting layer has a third thickness, the first thickness is less than the second thickness, and the third thickness is less than the first thickness.

11. The organic light-emitting element according to claim 10, wherein the maximum vertical height of the first lens is greater than the maximum vertical height of the second lens, and a maximum vertical height of the third lens is greater than the maximum vertical height of the first lens.

12. The organic light-emitting element according to claim 1, further comprising:
a flat layer, located above the second electrode; and
a cover plate, located over the flat layer,
wherein the lens is located within the flat layer.

13. The organic light-emitting element according to claim 12, wherein a convex surface of the lens faces the organic light-emitting layer.

14. The organic light-emitting element according to claim 1, further comprising:
a first flat layer, located above the second electrode, wherein the lens is located over the first flat layer;
a second flat layer, located above the first flat layer and covers the lens; and
a cover plate, located over the second flat layer.

15. The organic light-emitting element according to claim 14, wherein the convex surface of the lens faces the cover plate.

16. The organic light-emitting element according to claim 14, wherein the reflector is located between the first electrode and the substrate.

17. The organic light-emitting element according to claim 14, wherein the reflector is a first reflector, and the organic light-emitting element further comprises:
a second reflector, located between the second electrode and the cover plate,
wherein the lens is located between the second reflector and the cover plate.
